(19) United States
(12) Patent Application Publication
(10) Pub. No.: US 2024/0170737 A1
(43) Pub. Date: May 23, 2024

(54) LITHIUM METAL SECONDARY BATTERY, METHOD OF PRODUCING NEGATIVE ELECTRODE, AND METHOD OF CHARGING AND DISCHARGING LITHIUM METAL SECONDARY BATTERY

(71) Applicant: TOYOTA JIDOSHA KABUSHIKI KAISHA, Toyota-shi (JP)

(72) Inventors: Kohei MATSUNOBU, Toyota-shi (JP); Masaharu SENOUE, Seto-shi (JP)

(73) Assignee: TOYOTA JIDOSHA KABUSHIKI KAISHA, Toyota-shi (JP)

(21) Appl. No.: 18/488,662

(22) Filed: Oct. 17, 2023

(30) Foreign Application Priority Data
Nov. 21, 2022 (JP) 2022-185537

(51) Int. Cl. H01M 10/42; G03F 7/00; H01M 4/139; H01M 4/66; H01M 10/052; H01M 10/0568; H01M 10/0569; H01M 10/44

(52) U.S. Cl. CPC H01M 10/4235; G03F 7/70; H01M 4/139; H01M 4/667; H01M 10/052; H01M 10/0568; H01M 10/0569; H01M 10/44; H01M 2004/027

(57) ABSTRACT

A lithium metal secondary battery comprises a positive electrode, a negative electrode, and an electrolyte. The negative electrode includes a negative electrode current collector and a pillar layer. The pillar layer is placed on a surface of the negative electrode current collector. The pillar layer includes a plurality of electrically-insulating pillars. Each of the plurality of electrically-insulating pillars extends in a direction heading from the surface of the negative electrode current collector toward the positive electrode. Lithium ions are dissolved in the electrolyte. A charging reaction of the negative electrode is a deposition reaction of a lithium metal occurring in a gap between the electrically-insulating pillars. A discharging reaction of the negative electrode is a dissolution reaction of the lithium metal occurring in the gap.

### CROSS REFERENCE TO RELATED APPLICATIONS

This nonprovisional application is based on Japanese Patent Application No. 2022-185537 filed on Nov. 21, 2022, with the Japan Patent Office, the entire contents of which are hereby incorporated by reference.

### BACKGROUND

### Field

The present disclosure relates to a lithium metal secondary battery, a method of producing a negative electrode, and a method of charging and discharging a lithium metal secondary battery.

### Description of the Background Art

Japanese Patent Laying-Open No. 2001-250559 discloses a lithium metal secondary battery.

### SUMMARY

In a lithium metal secondary battery (hereinafter also called “a cell”), a charging reaction of the negative electrode is a deposition reaction of Li metal. As Li metal is deposited, the thickness of the negative electrode increases. As the thickness of the negative electrode increases, the cell may expand. Hence, an object of the present disclosure is to reduce expansion of a cell that can take place concomitantly with Li metal deposition.

Hereinafter, the technical configuration and effects of the present disclosure will be described. It should be noted that the action mechanism according to the present specification includes presumption. The action mechanism does not limit the technical scope of the present disclosure.
1. A lithium metal secondary battery comprises a positive electrode, a negative electrode, and an electrolyte. The negative electrode includes a negative electrode current collector and a pillar layer. The pillar layer is placed on a surface of the negative electrode current collector. The pillar layer includes a plurality of electrically-insulating pillars. Each of the plurality of electrically-insulating pillars extends in a direction heading from the surface of the negative electrode current collector toward the positive electrode. Lithium ions are dissolved in the electrolyte. A charging reaction of the negative electrode is a deposition reaction of a lithium metal occurring in a gap between the electrically-insulating pillars. A discharging reaction of the negative electrode is a dissolution reaction of the lithium metal occurring in the gap.

In the cell according to “1” above, the negative electrode includes a pillar layer. The pillar layer includes a plurality of electrically-insulating pillars. The plurality of electrically-insulating pillars may form a framework. Li metal may be deposited in a gap between the electrically-insulating pillars. It is conceivable that Li metal deposition is less likely to cause a change in the contour dimensions of the pillar layer (framework). As a result of Li metal deposition occurring only inside the framework, an increase in the thickness of the negative electrode may be reduced. That is, expansion of the cell that can take place concomitantly with Li metal deposition may be reduced.

It should be noted that the pillar is electrically insulating. If the pillar is electrically conductive, cell expansion may not be reduced, for the following reason. If the pillar is electrically conductive, electrons may be supplied to the pillar. Then, at the edge of the pillar (which is an area that is the closest to the positive electrode), Li ions can receive electrons to become Li metal to be deposited. During charging, the Li metal may grow toward the positive electrode. That is, the Li metal may spread in a direction away from the pillar layer. Due to this, it is conceivable to be difficult to contain the Li metal within the pillar layer (framework).

When the pillar is electrically insulating, at the start of charging, Li ions may receive electrons at the surface of the negative electrode current collector and Li metal may be deposited there. When Li metal deposition starts at the surface of the negative electrode current collector, Li metal may spread inside the pillar layer during charging.
2. In the lithium metal secondary battery according to “1” above, each of the plurality of electrically-insulating pillars may include a resist material, for example. For example, the plurality of electrically-insulating pillars may be formed by photolithography.
3. In the lithium metal secondary battery according to “1” or “2” above, each of the plurality of electrically-insulating pillars may have an aspect ratio of 1 or less, for example.

The “aspect ratio” is determined by the following equation (F-1):

A_{R}=H/D (F-1)

In the equation, A_{R} represents the aspect ratio. H represents a height of the electrically-insulating pillar. D represents a diameter of the electrically-insulating pillar.

It is expected that when the electrically-insulating pillar has an aspect ratio of 1 or less, the electrically-insulating pillar tends not to come off from the surface of the negative electrode current collector. Herein, the aspect ratio is a dimensionless amount.
4. In the lithium metal secondary battery according to any one of “1” to “3” above, each of the plurality of electrically-insulating pillars may have a diameter from 100 to 300 μm and a height from 1 to 100 μm, for example.
5. In the lithium metal secondary battery according to any one of “1” to “4” above, the electrolyte may include a solvent and a solute. The solvent may include a hydrofluoroether (HFE), for example. The solute may include an imide salt, for example.

When the electrolyte includes HFE and an imide salt, power output is expected to be enhanced, for example.
6. In the lithium metal secondary battery according to any one of “1” to “5” above, the pillar layer may have a gap rate from 50 to 95%, for example.

The “gap rate” is determined by the following equation (F-2):

P₀={(S₀−S₁)/S₀}×100 (F-2)

In the equation, P₀ represents the gap rate. The gap rate is expressed in percentage. S₀ represents an area of a region on which the pillar layer is placed, within an area of the negative electrode current collector. S₁ represents a total area to which the plurality of electrically-insulating pillars are adhered.

The higher the gap rate is, the more Li metal the pillar layer can store in it. That is, the more enhanced the energy density is expected to be. For example, there may be an occasion where pressure is applied in the thickness direction of the pillar layer (which is the height direction of the electrically-insulating pillar). For example, there may be an occasion where a restraint member is provided to restrain the outside of the cell and thereby pressure (restraining pressure) is generated. If the restraining pressure is applied locally on some of the electrically-insulating pillars, the amount of Li metal deposition may become nonuniform. For example, it is expected that the lower the gap rate is (the higher the density of the electrically-insulating pillars is), the more distributed the restraining pressure is among the plurality of electrically-insulating pillars. When the gap rate is from 50 to 95%, the balance between energy density and restraining pressure distribution tends to be good. Herein, the gap rate is a dimensionless amount. In the above equation (F-2), S₀ may be regarded as the area of the region (the shape) that is defined by the contour of the pillar layer in a plan view.
7. A method of producing a negative electrode for the lithium metal secondary battery according to any one of “1” to “6” above may include, for example, the following (a) to (c):
(a) preparing the negative electrode current collector;
(b) forming a resist layer by placing a resist material on the surface of the negative electrode current collector; and
(c) forming the pillar layer by selectively removing a part of the resist layer.

By photolithography, it is possible to perform patterning of the positions of the plurality of electrically-insulating pillars in a desired manner.
8. A method of charging and discharging a lithium metal secondary battery comprises the following (d) and (f):
(d) charging a lithium metal secondary battery; and
(f) discharging the lithium metal secondary battery.

A lithium metal secondary battery comprises a positive electrode, a negative electrode, and an electrolyte. The negative electrode includes a negative electrode current collector and a pillar layer. The pillar layer is placed on a surface of the negative electrode current collector. The pillar layer includes a plurality of electrically-insulating pillars. Each of the plurality of electrically-insulating pillars extends in a direction heading from the surface of the negative electrode current collector toward the positive electrode. Lithium ions are dissolved in the electrolyte.

The above (d) includes deposition of a lithium metal in a gap between the electrically-insulating pillars.

The above (f) includes dissolution of the lithium metal in the gap.
9. In the method of charging and discharging a lithium metal secondary battery according to “8” above, the lithium metal may become deposited so as to extend in mesh form in a plan view, for example.

In a plan view, the plurality of electrically-insulating pillars may be distributed in dot pattern. Thereby, in a plan view, gaps between the electrically-insulating pillars spread in mesh form. Due to this, Li metal may form a mesh-form contiguous phase within the gaps. As a result of the Li metal forming a contiguous phase, occurrence of isolated Li metal may be reduced. When isolated Li metal is present, the amount of Li metal deposition may become nonuniform.

Next, an embodiment of the present disclosure (which may also be simply called “the present embodiment” hereinafter) and an example of the present disclosure (which may also be simply called “the present example” hereinafter) will be described. It should be noted that neither the present embodiment nor the present example limits the technical scope of the present disclosure. The present embodiment and the present example are illustrative in any respect. The present embodiment and the present example are non-restrictive. The technical scope of the present disclosure encompasses any modifications within the meaning and the scope equivalent to the terms of the claims. For example, it is originally planned that certain configurations of the present embodiment and the present example can be optionally combined.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a conceptual view illustrating an example of a lithium metal secondary battery according to the present embodiment.

FIG. 2 is a schematic cross-sectional view of an electrically-insulating pillar according to the present embodiment.

FIG. 3 is a schematic plan view illustrating an example of a positioning pattern of electrically-insulating pillars.

FIG. 4 is a table showing a first cell configuration.

FIG. 5 is a table showing a second cell configuration.

FIG. 6 is a table showing a third cell configuration.

FIG. 7 is a schematic flowchart illustrating a method of producing a negative electrode according to the present embodiment.

FIG. 8 is a schematic flowchart illustrating a method of charging and discharging according to the present embodiment.

FIG. 9 is a conceptual view illustrating a battery system according to the present embodiment.

FIG. 10 is a table showing cell configurations and evaluation results.

FIG. 11 is a schematic plan view illustrating a framework of No. 4.

FIG. 12 is a conceptual view illustrating the deposition behavior of No. 1.

FIG. 13 is a conceptual view illustrating the deposition behavior of No. 2.

FIG. 14 is a conceptual view illustrating the deposition behavior of No. 3.

### DESCRIPTION OF THE PREFERRED EMBODIMENTS

### 1. Terms and Definitions Thereof, Etc.

Expressions such as “comprise”, “include”, and “have”, and other similar expressions (such as “be composed of”, for example) are open-ended expressions. In an open-ended expression, in addition to an essential component, an additional component may or may not be further included. The expression “consist of” is a closed-end expression. However, even when a closed-end expression is used, impurities present under ordinary circumstances as well as an additional element irrelevant to the technique according to the present disclosure are not excluded. The expression “consist essentially of” is a semiclosed-end expression. A semiclosed-end expression tolerates addition of an element that does not substantially affect the fundamental, novel features of the technique according to the present disclosure.

Expressions such as “may” and “can” are not intended to mean “must” (obligation) but rather mean “there is a possibility” (tolerance).

Regarding a plurality of steps, operations, processes, and the like that are included in various methods, the order for implementing those things is not limited to the described order, unless otherwise specified. For example, a plurality of steps may proceed simultaneously. For example, a plurality of steps may be implemented in reverse order.

A singular form also includes its plural meaning, unless otherwise specified. For example, “a particle” may mean not only “one particle” but also “a plurality of particles (a particle group)” and “a group of particles (powder)”.

Any geometric term (such as “parallel”, “vertical”, and “orthogonal”, for example) should not be interpreted solely in its exact meaning. For example, “parallel” may mean a geometric state that is deviated, to some extent, from exact “parallel”. Any geometric term herein may include tolerances and/or errors in terms of design, operation, production, and/or the like. The dimensional relationship in each figure may not necessarily coincide with the actual dimensional relationship. The dimensional relationship (in length, width, thickness, and the like) in each figure may have been changed for the purpose of assisting understanding for the readers. Further, a part of a given configuration may have been omitted.

“In a plan view” refers to viewing a target in a direction parallel to the thickness direction of the target. A plan view may correspond to a view in the XY plane in each figure. “In a cross-sectional view” refers to viewing a target in a direction orthogonal to the thickness direction of the target. A cross-sectional view may correspond to a view in the XZ plane and/or the YZ plane in each figure.

“Pillar (cylinder)” refers to a three-dimensional body that includes two bottom faces (a first bottom face, a second bottom face) and a side face. These two bottom faces may be parallel to each other. The height (H) of the pillar is the distance between the first bottom face and the second bottom face. The direction parallel to the height is the height direction (which may also be referred to as “the axial direction”). The diameter (D) of the pillar refers to the diameter of the first bottom face or the second bottom face. When the diameter of the first bottom face is different from the diameter of the second bottom face, the larger diameter is regarded as the diameter of the pillar. When the bottom face is not circular, the diameter refers to the maximum Feret diameter.

A numerical range such as “from m to n %” includes both the upper limit and the lower limit, unless otherwise specified. That is, “from m to n %” means a numerical range of “not less than m % and not more than n %”. Moreover, “not less than m % and not more than n %” includes “more than m % and less than n %”. Further, any numerical value selected from a certain numerical range may be used as a new upper limit or a new lower limit. For example, any numerical value from a certain numerical range may be combined with any numerical value described in another location of the present specification or in a table or a drawing to set a new numerical range.

All the numerical values are regarded as being modified by the term “about”. The term “about” may mean±5%, ±3%, ±1%, and/or the like, for example. Each numerical value may be an approximate value that can vary depending on the implementation configuration of the technique according to the present disclosure. Each numerical value may be expressed in significant figures. Unless otherwise specified, each measured value may be the average value obtained from multiple measurements performed. The number of measurements may be 3 or more, or may be 5 or more, or may be 10 or more. Generally, the greater the number of measurements is, the more reliable the average value is expected to be. Each measured value may be rounded off based on the number of the significant figures. Each measured value may include an error occurring due to an identification limit of the measurement apparatus, for example.

A stoichiometric composition formula represents a typical example of a compound. A compound may have a non-stoichiometric composition. For example, “Al₂O₃” is not limited to a compound where the ratio of the amount of substance (molar ratio) is “Al/O=2/3”. “Al₂O₃” represents a compound that includes Al and O in any composition ratio, unless otherwise specified. Further, the compound may be doped with a trace element, or some of Al and/or O may be replaced by another element, for example.

“Derivative” refers to a compound that is derived from its original compound by at least one partial modification selected from the group consisting of functional group introduction, atom replacement, oxidation, reduction, and other chemical reactions. The position of modification may be one position, or may be a plurality of positions. “Substituent” may include, for example, at least one selected from the group consisting of alkyl group, alkenyl group, alkynyl group, cycloalkyl group, unsaturated cycloalkyl group, aromatic group, heterocyclic group, halogen atom (F, Cl, Br, I, etc.), OH group, SH group, CN group, SCN group, OCN group, nitro group, alkoxy group, unsaturated alkoxy group, amino group, alkylamino group, dialkylamino group, aryloxy group, acyl group, alkoxycarbonyl group, acyloxy group, aryloxycarbonyl group, acylamino group, alkoxycarbonylamino group, aryloxy carbonylamino group, sulfonylamino group, sulfamoyl group, carbamoyl group, alkylthio group, arylthio group, sulfonyl group, sulfinyl group, ureido group, phosphoramide group, sulfo group, carboxy group, hydroxamic acid group, sulfino group, hydrazino group, imino group, silyl group, and the like. These substituents may be further substituted. When there are two or more substituents, these substituents may be the same as one another or may be different from each other. A plurality of substituents may be bonded together to form a ring.

### 2. Lithium Metal Secondary Battery

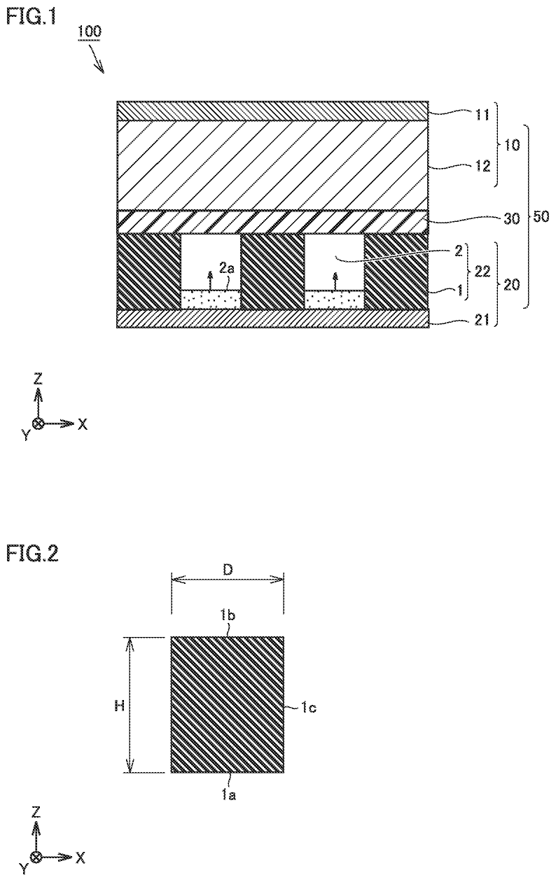

FIG. 1 is a conceptual view illustrating an example of a lithium metal secondary battery according to the present embodiment. A cell 100 includes a power generation element 50 and an electrolyte (not illustrated).

### 2-1. Exterior Package

Cell 100 may include an exterior package (not illustrated). The exterior package may accommodate power generation element 50 and the electrolyte. The exterior package may have any configuration. The exterior package may be a case made of metal, or may be a pouch made of a metal foil laminated film, for example. The case may have any shape. The case may be cylindrical, prismatic, flat, coin-shaped, and/or the like, for example. The exterior package may include Al and/or the like, for example. The exterior package may accommodate a single power generation element 50, or may accommodate a plurality of power generation elements 50, for example. The plurality of power generation elements 50 may form a series circuit, or may form a parallel circuit, for example. Inside the exterior package, the plurality of power generation elements 50 may be stacked in the thickness direction of cell 100.

### 2-2. Power Generation Element

Power generation element 50 includes a positive electrode 10 and a negative electrode 20. Power generation element 50 may further include a separator 30. Separator 30 is interposed between positive electrode 10 and negative electrode 20. Power generation element 50 may have any configuration. For example, power generation element 50 may be a stack-type one. For example, positive electrode 10 and negative electrode 20 may be alternately stacked with separator 30 interposed between positive electrode 10 and negative electrode 20 to form power generation element 50. For example, power generation element 50 may be a wound-type one. For example, positive electrode 10 having a belt-like shape, separator 30 having a belt-like shape, and negative electrode 20 having a belt-like shape may be stacked to form a stacked body. The resulting stacked body may be wound spirally to form power generation element 50. After being wound, the wound power generation element 50 may be shaped into a flat form.

Power generation element 50 may have an anode-free structure, for example. The “anode-free structure” refers to a structure in which no solid negative electrode active material is present before initial charging. It would be obvious that power generation element 50 may not have the anode-free structure.

### 2-3. Negative Electrode

Negative electrode 20 may be in sheet form, for example. Negative electrode 20 includes a negative electrode current collector 21 and a pillar layer 22.

### 2-3-1. Negative Electrode Current Collector

Negative electrode current collector 21 is electrically conductive. Negative electrode current collector 21 supports pillar layer 22 (a plurality of electrically-insulating pillars 1). Negative electrode current collector 21 may be in sheet form, for example. Negative electrode current collector 21 may have a thickness from 5 to 50 μm, for example. Negative electrode current collector 21 may include a metal foil and/or the like, for example. Negative electrode current collector 21 may include, for example, at least one selected from the group consisting of Cu, Ni, Fe, Zn, Pb, Ag, and Au. Negative electrode current collector 21 may include a Cu foil, a Cu alloy foil, and/or the like, for example.

### 2-3-2. Pillar Layer

Pillar layer 22 is placed on the surface of negative electrode current collector 21. Pillar layer 22 may be placed on only one side of negative electrode current collector 21. Pillar layer 22 may be placed on both sides of negative electrode current collector 21. Pillar layer 22 includes the plurality of electrically-insulating pillars 1. The plurality of electrically-insulating pillars 1 may be fixed to the surface of negative electrode current collector 21, for example. The plurality of electrically-insulating pillars 1 may be adhered to the surface of negative electrode current collector 21, for example.

The plurality of electrically-insulating pillars 1 stand together, and between these electrically-insulating pillars 1, a gap 2 is formed. Inside the gap 2, a charge-discharge reaction (a dissolution-deposition reaction of Li metal 2a) may proceed.

FIG. 2 is a schematic cross-sectional view of an electrically-insulating pillar according to the present embodiment. Electrically-insulating pillar 1 includes a first bottom face 1a, a second bottom face 1b, and a side face 1c. Side face 1c connects first bottom face 1a with second bottom face 1b. Electrically-insulating pillar 1 may be cylindrical or may be prismatic, for example. More specifically, side face 1c may be a curved face, or may include a plurality of flat planes. First bottom face 1a is adhered to the surface of negative electrode current collector 21. Second bottom face 1b may be in contact with separator 30, for example. Second bottom face 1b may be in contact with positive electrode 10, for example.

As long as first bottom face 1a is fixed to negative electrode current collector 21, each of first bottom face 1a and second bottom face 1b may not be a flat face, for example. Second bottom face 1b may be a curved face, for example. Second bottom face 1b may protrude in a semi-round shape, for example. That is, electrically-insulating pillar 1 may form a pillar bump.

Each electrically-insulating pillar 1 extends in a direction heading from the surface of negative electrode current collector 21 toward positive electrode 10. That is, the height direction of electrically-insulating pillar 1 is along the thickness direction of negative electrode 20 (pillar layer 22). The height direction of electrically-insulating pillar 1 may be parallel to the thickness direction of pillar layer 22. Electrically-insulating pillar 1 may be a right cylinder or may be an oblique cylinder, for example. The angle between first bottom face 1a (second bottom face 1b) and side face 1c may be from 15 to 90°, or from 30 to 90°, or from 45 to 90°, or from 60 to 90°, or from 75 to 90°, for example. It is conceivable that as the angle approaches to 90° (namely, as the shape of electrically-insulating pillar 1 approaches to a right cylinder), the tortuosity rate may decrease. The “tortuosity rate” refers to a value obtained by dividing the path length by the thickness of pillar layer 22. The “path length” refers to the distance Li ions travel when they permeate through pillar layer 22 in the thickness direction. The minimum value of the tortuosity rate is 1. The lower the tortuosity rate is, the more enhanced the power output is expected to be, for example. Pillar layer 22 may have a tortuosity rate from 1 to 1.5, or from 1 to 1.2, or from 1 to 1.1, or from 1 to 1.05, for example.

Electrically-insulating pillar 1 may have a height (H) from 1 to 1000 μm, for example. That is, pillar layer 22 may have a thickness from 1 to 1000 μm. The height of electrically-insulating pillar 1 may be from 1 to 500 μm, or from 1 to 300 μm, or from 1 to 100 μm, or from 10 to 100 μm, or from 50 to 100 μm, or from 50 to 70 μm, for example.

Electrically-insulating pillar 1 may have a diameter (D) from 1 to 1000 μm, for example. Electrically-insulating pillar 1 may have a diameter from 5 to 500 μm, or from 100 to 300 μm, or from 140 to 240 μm, for example. The diameter of electrically-insulating pillar 1 may be larger than the average pore size of separator 30, for example. In the height direction of electrically-insulating pillar 1, the diameter of electrically-insulating pillar 1 may be constant or may change. When the diameter is constant, the tortuosity rate may decrease.

Electrically-insulating pillar 1 may have an aspect ratio (A_{R}=H/D) of 1 or less, for example. When electrically-insulating pillar 1 has an aspect ratio of 1 or less, it is expected that electrically-insulating pillar 1 tends not to come off from the surface of negative electrode current collector 21. Electrically-insulating pillar 1 may have an aspect ratio from 0.1 to 0.99, or from 0.1 to 0.8, or from 0.2 to 0.6, or from 0.27 to 0.45, for example.

Pillar layer 22 is formed of a group of electrically-insulating pillars 1. For example, pillar layer 22 may be referred to as “a pillar array”, in other words. The positioning pattern of electrically-insulating pillars 1 is not limited. The positioning pattern may be orderly, or may be disorderly.

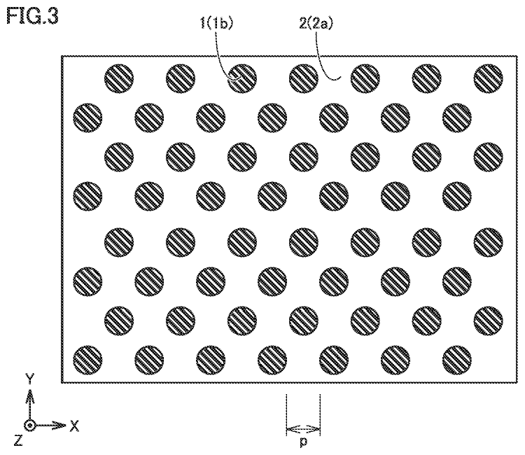

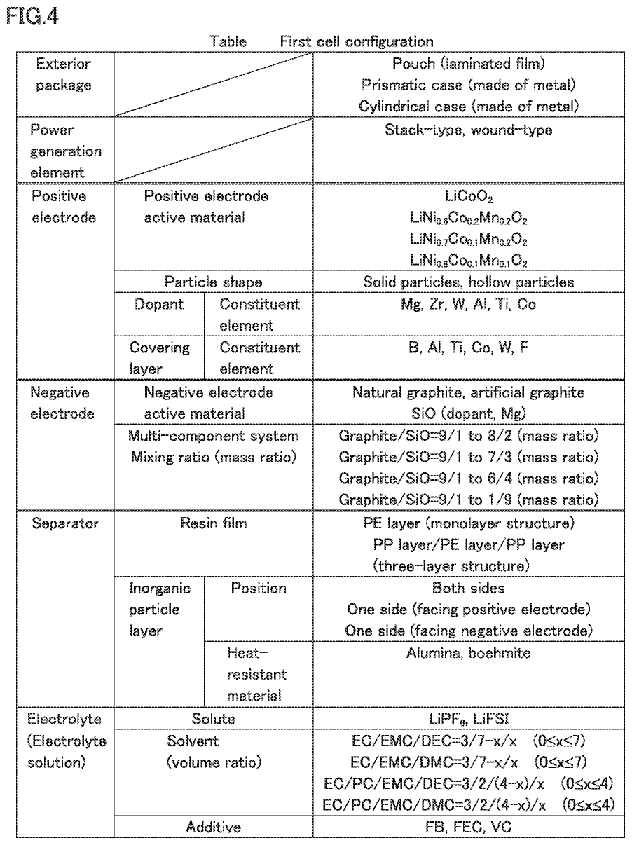

FIG. 3 is a schematic plan view illustrating an example of a positioning pattern of electrically-insulating pillars. Electrically-insulating pillars 1 may be distributed in dot pattern, for example. Electrically-insulating pillars 1 may be positioned in lattice, for example. Electrically-insulating pillars 1 may be positioned in the shape of a triangle lattice, the shape of an isosceles triangle lattice, the shape of a regular triangle lattice, the shape of a rectangular lattice, the shape of a square lattice, and/or the like, for example. FIG. 3 shows an example where electrically-insulating pillars 1 are positioned in the shape of a triangle lattice.

The planar shape of first bottom face 1a and second bottom face 1b is not limited. The planar shape of first bottom face 1a and the planar shape of second bottom face 1b may be the same as one another, or may be different from each other. The planar shape of each of first bottom face 1a and second bottom face 1b, independently, may be circular, elliptical, triangular, rectangular, square, hexagonal, and/or the like. FIG. 3 shows an example where second bottom face 1b is circular.

“(The plurality of) Electrically-insulating pillars 1” refers to two or more electrically-insulating pillars 1. The upper limit to the number is not limited. Similarly, the number density of electrically-insulating pillars 1 in a plan view is also not limited. The number density may be from 1 to 1000/mm², or from 5 to 500/mm², or from 10 to 100/mm², or from 10 to 30/mm², for example.

In a plan view, electrically-insulating pillars 1 may be positioned at regular intervals, for example. The distance between electrically-insulating pillars 1 (“pitch (p)”) may be from 1 to 1000 μm, or from 5 to 500 μm, or from 10 to 300 μm, or from 50 to 500 μm, for example. The pitch may be larger than the average pore size of separator 30, for example.

Gaps 2 may be contiguous in mesh form. Pillar layer 22 may have a gap rate from 1 to 99%, or from 5 to 95%, or from 10 to 95%, or from 30 to 95%, or from 50 to 95%, for example. When the gap rate is from 50 to 95%, the balance between energy density and restraining pressure distribution tends to be good. The gap rate may be 50% or more, or may be 60% or more, or may be 70% or more, or may be 80% or more, or may be 90% or more, for example. The gap rate may be 90% or less, or may be 80% or less, or may be 70% or less, or may be 60% or less, for example.

Electrically-insulating pillar 1 is electrically insulating. Electrically-insulating pillar 1 may have a volume resistivity of 1×10⁵ Ω·cm or more, for example. Electrically-insulating pillar 1 may have a volume resistivity of 1×10¹⁰ Ω·cm or more, or 1×10¹⁵ Ω·cm or more, for example.

Electrically-insulating pillar 1 may be formed of any material as long as it is electrically insulating. Electrically-insulating pillar 1 may be insoluble in the electrolyte. Electrically-insulating pillar 1 may include ceramic material, glass material, and/or the like, for example. Electrically-insulating pillar 1 may include, for example, at least one selected from the group consisting of SiO₂, GeO₂, B₂O₃, P₂O₅, As₂O₅, Li₂O, Na₂O, K₂O, MgO, CaO, BaO, Al₂O₃, TiO₂, and ZrO₂.

Electrically-insulating pillar 1 may include resin material, for example. Electrically-insulating pillar 1 may include engineering plastic, super engineering plastic, and/or the like, for example. Electrically-insulating pillar 1 may include, for example, at least one selected from the group consisting of polyethylene (PE), polypropylene (PP), polyvinylidene difluoride (PVdF), polytetrafluoroethylene (PTFE), polyimide (PI), polyamide (PA), and polyamide-imide (PAI).

Electrically-insulating pillars 1 may include a resist material, for example. When electrically-insulating pillars 1 include a resist material, electrically-insulating pillars 1 may be formed by photolithography. The resist material may be positive-type, or may be negative-type, for example. The resist material may include, for example, at least one selected from the group consisting of a phenolic resin (such as a novolac resin, for example), an acrylic resin, and a methacrylic resin.

### 2-3-3. Seed Particles

Negative electrode 20 may further include seed particles (not illustrated), for example. The seed particles may serve as seeds for Li nucleation during charging. The seed particles may be placed on the surface of negative electrode current collector 21, for example. The seed particles may be placed inside the gaps 2. The seed particles may include, for example, at least one selected from the group consisting of Li, Mg, Al, Zn, Ag, Pt, and Au. The seed particles may be nanoparticles, for example. The seed particles may have a D50 from 1 to 200 nm, for example.

### 2-3-4. Second Negative Electrode Active Material

Negative electrode 20 may further include a negative electrode active material other than Li (hereinafter also called “a second negative electrode active material”), for example. The second negative electrode active material may include insertion-based active material, alloy-based active material, and/or the like, for example. A combination of Li metal and an insertion-based active material can enhance cycle endurance and/or the like, for example. The second negative electrode active material may be in particle form, for example. The second negative electrode active material may be placed inside the gap 2, for example. The second negative electrode active material may be placed on the surface of negative electrode current collector 21, for example.

The second negative electrode active material may include, for example, at least one selected from the group consisting of natural graphite, artificial graphite, soft carbon, hard carbon, silicon (Si), SiO, Li silicate, Si-based alloy, tin (Sn), SnO, Sn-based alloy, and Li₄Ti₅O₁₂.

### 2-3-4-1. Carbon-Based Active Material

“Graphite” collectively refers to natural graphite and artificial graphite. Graphite may be a mixture of natural graphite and artificial graphite. The mixing ratio (mass ratio) may be “(natural graphite)/(artificial graphite)=1/9 to 9/1”, “(natural graphite)/(artificial graphite)=2/8 to 8/2”, or “(natural graphite)/(artificial graphite)=3/7 to 7/3”, for example.

Graphite may include a dopant. The dopant may include, for example, at least one selected from the group consisting of B, N, P, Li, and Ca. The amount to be added, in molar fraction, may be from 0.01 to 5%, or from 0.1 to 3%, or from 0.1 to 1%, for example.

The surface of graphite may be covered with amorphous carbon, for example. The surface of graphite may be covered with another type of material, for example. This another type of material may include, for example, at least one selected from the group consisting of P, W, Al, and O. The another type of material may include, for example, at least one selected from the group consisting of Al(OH)₃, AlOOH, Al₂O₃, WO₃, Li₂CO₃, LiHCO₃, and Li₃PO₄.

### 2-3-4-2. Alloy-Based Active Material

SiO may be represented by the following formula (A-1), for example.

SiOₓ (A-1)

In the above formula, the relationship of 0<x<2 is satisfied.

In the above formula (A-1), x may satisfy 0.5≤x≤1.5 or 0.8≤x≤1.2, for example.

Li silicate may include, for example, at least one selected from the group consisting of Li₄SiO₄, Li₂SiO₃, Li₂Si₂O₅, and Li₈SiO₆. The second negative electrode active material may include a mixture of Si and Li silicate, for example. The mixing ratio (mass ratio) may be “Si/(Li silicate)=1/9 to 9/1”, “Si/(Li silicate)=2/8 to 8/2”, “Si/(Li silicate)=3/7 to 7/3”, or “Si/(Li silicate)=4/6 to 6/4”, for example.

The alloy-based active material (such as Si, SiO) may include an additive. The additive may be a substituted solid solution atom or an intruding solid solution atom, for example. The additive may be an adherent adhered to the surface of the alloy-based active material. The adherent may be an elementary substance, an oxide, a carbide, a nitride, a halide, and/or the like, for example. The amount to be added may be, in molar fraction, from 0.01 to 5%, or from 0.1 to 3%, or from 0.1 to 1%, for example. The additive may include, for example, at least one selected from the group consisting of Li, Na, K, Rb, Be, Mg, Ca, Sr, Fe, Ba, B, Al, Ga, In, C, Ge, Sn, Pb, N, P, As, Y, Sb, and S. That is, SiO may be doped with Mg and/or Na. For example, Mg silicate and/or Na silicate, etc., may be formed. For example, boron oxide (such as B₂O₃, for example), yttrium oxide (such as Y₂O₃, for example), and/or the like may be added to SiO.

### 2-3-4-3. Si—C Composite Material

The second negative electrode active material may include a composite material of the carbon-based active material (such as graphite) and the alloy-based active material (such as Si), for example. A composite material including Si and carbon may also be called “a Si—C composite material”. For example, Si microparticles may be dispersed inside carbon particles. For example, Si microparticles may be dispersed inside graphite particles. For example, Li silicate particles may be covered with a carbon material (such as amorphous carbon). The Si—C composite material and graphite may be mixed together for use.

### 2-3-4-4. Multi-Component System

The second negative electrode active material may include two or more components. The second negative electrode active material may include the carbon-based active material (such as graphite) and the alloy-based active material (such as Si, SiO). The mixing ratio (mass ratio) of the carbon-based active material and the alloy-based active material may be “(carbon-based active material)/(alloy-based active material)=1/9 to 9/1”, “(carbon-based active material)/(alloy-based active material)=2/8 to 8/2”, “(carbon-based active material)/(alloy-based active material)=3/7 to 7/3”, or “(carbon-based active material)/(alloy-based active material)=4/6 to 6/4”, for example.

### 2-3-4-5. Binder

The second negative electrode active material may be fixed to negative electrode current collector 21 and/or the like by means of a binder, for example. The binder may include any component. The binder may include, for example, at least one selected from the group consisting of polyacrylic acid (PAA), carboxymethylcellulose (CMC), styrene-butadiene rubber (SBR), acrylate butadiene rubber (ABR), polyacrylonitrile (PAN), and derivatives of these.

### 2-4. Positive Electrode

Positive electrode 10 may be in sheet form, for example. Positive electrode 10 may include a positive electrode current collector 11 and a positive electrode active material layer 12, for example. Positive electrode current collector 11 is electrically conductive. Positive electrode current collector 11 supports positive electrode active material layer 12. Positive electrode current collector 11 may be in sheet form, for example. Positive electrode current collector 11 may have a thickness from 5 to 50 μm, for example. Positive electrode current collector 11 may include a metal foil, for example. Positive electrode current collector 11 may include, for example, at least one selected from the group consisting of Al, Mn, Ti, Fe, and Cr. Positive electrode current collector 11 may include an Al foil, an Al alloy foil, a Ti foil, a stainless steel (SUS) foil, and/or the like, for example.

Between positive electrode current collector 11 and positive electrode active material layer 12, an intermediate layer (not illustrated) may be formed. The intermediate layer does not include a positive electrode active material. The intermediate layer may have a thickness from 0.1 to 5 μm, for example. The intermediate layer may include a conductive material, an insulation material, a binder, and/or the like, for example. The conductive material and the binder are described below. The insulation material may include alumina, boehmite, aluminum hydroxide, and/or the like, for example.

Positive electrode active material layer 12 is placed on the surface of positive electrode current collector 11. Positive electrode active material layer 12 may be placed on only one side of positive electrode current collector 11. Positive electrode active material layer 12 may be placed on both sides of positive electrode current collector 11. Positive electrode active material layer 12 may have a thickness from 10 to 1000 μm, or from 50 to 500 μm, or from 100 to 300 μm, for example. Positive electrode active material layer 12 includes a positive electrode active material. Positive electrode active material layer 12 may further include a conductive material, a binder, and the like, for example.

### 2-4-1. Conductive Material

The conductive material may form an electron conduction path inside the positive electrode active material layer 12. The amount of the conductive material to be used may be, for example, from 0.1 to 10 parts by mass relative to 100 parts by mass of the positive electrode active material. The conductive material may include any component. The conductive material may include, for example, at least one selected from the group consisting of graphite, acetylene black (AB), Ketjenblack (registered trademark), vapor grown carbon fiber (VGCF), carbon nanotube (CNT), and graphene flake (GF).

### 2-4-2. Binder

The binder is capable of fixing positive electrode active material layer 12 to positive electrode current collector 11. The amount of the binder to be used may be, for example, from 0.1 to 10 parts by mass relative to 100 parts by mass of the positive electrode active material. The binder may include any component. The binder may include, for example, at least one selected from the group consisting of polyvinylidene difluoride (PVdF), vinylidene difluoride-hexafluoropropylene copolymer (PVdF-HFP), tetrafluoroethylene (PTFE), CMC, PAA, polyvinyl alcohol (PVA), polyvinylpyrrolidone (PVP), polyoxyethylene alkyl ether, and derivatives of these.

### 2-4-3. Other Components

Positive electrode active material layer 12 may further include an inorganic filler, an organic filler, a solid electrolyte, a surface modifier, a lubricant, a flame retardant, a protective agent, a flux, a coupling agent, an adsorbent, and/or the like, for example. Positive electrode active material layer 12 may include polyoxyethylene allylphenyl ether phosphate, zeolite, a silane coupling agent, MoS₂, WO₃, and/or the like, for example.

### 2-4-4. Positive Electrode Active Material

The positive electrode active material may be in particle form, for example. The positive electrode active material may include any component. The positive electrode active material may include a transition metal oxide, a polyanion compound, and/or the like, for example. In a single particle (positive electrode active material), the composition may be uniform, or may be non-uniform. For example, there may be a gradient in the composition from the surface of the particle toward the center. The composition may change contiguously, or may change non-contiguously (in steps).

### 2-4-4-1. Transition Metal Oxide (Space Group R-3m)

The transition metal oxide may have any crystal structure. For example, the transition metal oxide may include a crystal structure that belongs to a space group R-3m and/or the like. For example, a compound represented by the general formula “LiMO₂” may have a crystal structure that belongs to a space group R-3m. The transition metal oxide may be represented by the following formula (C-1), for example.

Li₁₋ₐNiₓM₁₋ₓO₂ (C-1)

In the above formula, the relationships of −0.5≤a≤0.5, 0<x≤1 are satisfied.

M may include, for example, at least one selected from the group consisting of Co, Mn, and Al.

In the above formula (C-1), x may satisfy the relationship of 0<x≤0.1, 0.1≤x≤0.2, 0.2≤x≤0.3, 0.3≤x≤0.4, 0.4≤x≤0.5, 0.5≤x≤0.6, 0.6≤x≤0.7, 0.7≤x≤0.8, 0.8≤x≤0.9, or 0.9≤x≤1, for example, a may satisfy the relationship of −0.4≤a≤0.4, −0.3≤a≤0.3, −0.2≤a≤0.2, or −0.1≤a≤0.1, for example.

The transition metal oxide may include, for example, at least one selected from the group consisting of LiCoO₂, LiMnO₂, LiNi_{0.9}Co_{0.1}O₂, LiNi_{0.9}Mn_{0.1}O₂, and LiNiO₂.

### 2-4-4-2. NCM

The transition metal oxide may be represented by the following formula (C-2), for example. A compound represented by the following formula (C-2) may also be called “NCM”.

Li₁₋ₐNiₓCo_{y}Mn₂O₂ (C-2)

In the above formula, the relationships of −0.5≤a≤0.5, 0<x<1, 0<y<1, 0<z<1, x+y+z=1 are satisfied.

In the above formula (C-2), x may satisfy the relationship of 0<x≤0.1, 0.1≤x≤0.2, 0.2≤x≤0.3, 0.3≤x≤0.4, 0.4≤x≤0.5, 0.5≤x≤0.6, 0.6≤x≤0.7, 0.7≤x≤0.8, 0.8≤x≤0.9, or 0.9≤x<1, for example.

In the above formula (C-2), y may satisfy the relationship of 0<y≤0.1, 0.1≤y≤0.2, 0.2≤y≤0.3, 0.3≤y≤0.4, 0.4≤y≤0.5, 0.5≤y≤0.6, 0.6≤y≤0.7, 0.7≤y≤0.8, 0.8≤y≤0.9, or 0.9≤y<1, for example.

In the above formula (C-2), z may satisfy the relationship of 0<z≤0.1, 0.1≤z≤0.2, 0.2≤z≤0.3, 0.3≤z≤0.4, 0.4≤z≤0.5, 0.5≤z≤0.6, 0.6≤z≤0.7, 0.7≤z≤0.8, 0.8≤z≤0.9, or 0.9≤z<1, for example.

NCM may include, for example, at least one selected from the group consisting of LiNi_{1/3}Co_{1/3}Mn_{1/3}O₂, LiNi_{0.4}Co_{0.3}Mn_{0.3}O₂, LiNi_{0.3}Co_{0.4}Mn_{0.3}O₂, LiNi_{0.3}Co_{0.3}Mn_{0.4}O₂, LiNi_{0.5}Co_{0.2}Mn_{0.3}O₂, LiNi_{0.5}Co_{0.3}Mn_{0.2}O₂, LiNi_{0.5}Co_{0.4}Mn_{0.1}O₂, LiNi_{0.5}Co_{0.1}Mn_{0.4}O₂, LiNi_{0.6}Co_{0.2}Mn_{0.2}O₂, LiNi_{0.6}Co_{0.3}Mn_{0.1}O₂, LiNi_{0.6}Co_{0.1}Mn_{0.3}O₂, LiNi_{0.7}Co_{0.1}Mn_{0.2}O₂, LiNi_{0.7}Co_{0.2}Mn_{0.1}O₂, LiNi_{0.8}Co_{0.1}Mn_{0.1}O₂, and LiNi_{0.9}Co_{0.05}Mn_{0.05}O₂.

### 2-4-4-3. NCA

The transition metal oxide may be represented by the following formula (C-3), for example. A compound represented by the following formula (C-3) may also be called “NCA”.

Li₁₋ₐNiₓCo_{y}Al₂O₂ (C-3)

In the above formula, the relationships of −0.5≤a≤0.5, 0<x<1, 0<y<1, 0<<1, x+y+z=1 are satisfied.

In the above formula (C-3), x may satisfy the relationship of 0<x≤0.1, 0.1≤x≤0.2, 0.2≤x≤0.3, 0.3≤x≤0.4, 0.4≤x≤0.5, 0.5≤x≤0.6, 0.6≤x≤0.7, 0.7≤x≤0.8, 0.8≤x≤0.9, or 0.9≤x<1, for example.

In the above formula (C-3), y may satisfy the relationship of 0<y≤0.1, 0.1≤y≤0.2, 0.2≤y≤0.3, 0.3≤y≤0.4, 0.4≤y≤0.5, 0.5≤y≤0.6, 0.6≤y≤0.7, 0.7≤y≤0.8, 0.8≤y≤0.9, or 0.9≤y<1, for example.

In the above formula (C-3), z may satisfy the relationship of 0<z≤0.1, 0.1≤z≤0.2, 0.2≤z≤0.3, 0.3≤z≤0.4, 0.4≤z≤0.5, 0.5≤z≤0.6, 0.6≤z≤0.7, 0.7≤z≤0.8, 0.8≤z≤0.9, or 0.9≤z<1, for example.

NCA may include, for example, at least one selected from the group consisting of LiNi_{0.7}Co_{0.1}Al_{0.2}O₂, LiNi_{0.7}Co_{0.2}Al_{0.1}O₂, LiNi_{0.8}Co_{0.1}Al_{0.1}O₂, LiNi_{0.8}Co_{0.17}Al_{0.03}O₂, LiNi_{0.8}Co_{0.15}Al_{0.05}O₂, and LiNi_{0.9}Co_{0.05}Al_{0.05}O₂.

### 2-4-4-4. Multi-Component System

The positive electrode active material may include two or more NCMs and/or the like, for example. The positive electrode active material may include NCM (0.6≤x) and NCM (x<0.6), for example. “NCM (0.6≤x)” refers to a compound in which x (Ni ratio) in the above formula (C-2) is 0.6 or more. NCM (0.6≤x) may also be called “a high-nickel material”, for example. NCM (0.6≤x) includes LiNi_{0.8}Co_{0.1}Mn_{0.1}O₂ and/or the like, for example. “NCM(x<0.6)” refers to a compound in which x (Ni ratio) in the above formula (C-2) is less than 0.6. NCM (x<0.6) includes LiNi_{1/3}Co_{1/3}Mn_{1/3}O₂ and/or the like, for example. The mixing ratio (mass ratio) between NCM (0.6≤x) and NCM (x<0.6) may be “NCM (0.6≤x)/NCM (x<0.6)=9/1 to 1/9”, or “NCM (0.6≤x)/NCM (x<0.6)=9/1 to 4/6”, or “NCM (0.6≤x)/NCM (x<0.6)=9/1 to 3/7”, for example.

The positive electrode active material may include NCA and NCM, for example. The mixing ratio (mass ratio) between NCA and NCM may be “NCA/NCM=9/1 to 1/9”, “NCA/NCM=9/1 to 4/6”, or “NCA/NCM=9/1 to 3/7”, for example. Between NCA and NCM, the Ni ratio may be the same or may be different. The Ni ratio of NCA may be more than the Ni ratio of NCM. The Ni ratio of NCA may be less than the Ni ratio of NCM.

### 2-4-4-5. Transition Metal Oxide (Space Group C2/m)

The transition metal oxide may include a crystal structure that belongs to a space group C2/m and/or the like, for example. The transition metal oxide may be represented by the following formula (C-4), for example.

Li₂MO₃ (C-4)

In the above formula, M may include, for example, at least one selected from the group consisting of Ni, Co, Mn, and Fe.

The positive electrode active material may include a mixture of LiMO₂ (space group R-3m) and Li₂MO₃ (space group C2/m), for example. The positive electrode active material may include a solid solution that is formed of LiMO₂ and Li₂MO₃ (Li₂MO₃-LiMO₂), and/or the like, for example.

### 2-4-4-6. Transition Metal Oxide (Space Group Fd-3m)

The transition metal oxide may include a crystal structure that belongs to a space group Fd-3m, and/or the like, for example. The transition metal oxide may be represented by, for example, the following formula (C-5):

LiMn₂₋ₓMₓO₄ (C-5)

where the relationship of 0≤x≤2 is satisfied.

M may include, for example, at least one selected from the group consisting of Ni, Fe, and Zn.

LiM₂O₄ (space group Fd-3m) may include, for example, at least one selected from the group consisting of LiMn₂O₄ and LiMn_{1.5}Ni_{0.5}O₄. The positive electrode active material may include a mixture of LiMO₂ (space group R-3m) and LiM₂O₄ (space group Fd-3m), for example. The mixing ratio (mass ratio) between LiMO₂ (space group R-3m) and LiM₂O₄ (space group Fd-3m) may be “LiMO₂/LiM₂O₄=9/1 to 9/1”, “LiMO₂/LiM₂O₄=9/1 to 5/5”, or “LiMO₂/LiM₂O₄=9/1 to 7/3”, for example.

### 2-4-4-7. Polyanion Compound

The polyanion compound may include a phosphoric acid salt (such as LiFePO₄ for example), a silicic acid salt, a boric acid salt, and/or the like, for example. The polyanion compound may be represented by the following formulae (C-6) to (C-9), for example.

LiMPO₄ (C-6)

Li₂₋ₓMPO₄F (C-7)

Li₂MSiO₄ (C-8)

LiMBO₃ (C-9)

In the above formulae (C-6) to (C-9), M may include, for example, at least one selected from the group consisting of Fe, Mn, Co. In the above formula (C-7), the relationship of 0≤x≤2 may be satisfied, for example.

The positive electrode active material may include a mixture of LiMO₂ (space group R-3m) and the polyanion compound, for example. The mixing ratio (mass ratio) between LiMO₂ (space group R-3m) and the polyanion compound may be “LiMO₂/(polyanion compound)=9/1 to 9/1”, “LiMO₂/(polyanion compound)=9/1 to 5/5”, or “LiMO₂/(polyanion compound)=9/1 to 7/3”, for example.

### 2-4-4-8. Dopant

To the positive electrode active material, a dopant may be added. The dopant may be diffused throughout the entire particle, or may be locally distributed. For example, the dopant may be locally distributed on the particle surface. The dopant may be a substituted solid solution atom, or may be an intruding solid solution atom. The amount of the dopant to be added (the molar fraction relative to the total amount of the positive electrode active material) may be from 0.01 to 5%, or may be from 0.1 to 3%, or may be from 0.1 to 1%, for example. A single type of dopant may be added, or two or more types of dopant may be added. The two or more dopants may form a complex.

The dopant may include, for example, at least one selected from the group consisting of B, C, N, a halogen, Si, Na, Mg, Al, Mn, Co, Cr, Sc, Ti, V, Cu, Zn, Ga, Ge, Se, Sr, Y, Zr, Nb, Mo, In, Pb, Bi, Sb, Sn, W, La, Ce, Pr, Nd, Pm, Sm, Eu, Gd, Tb, Dy, Ho, Er, Tm, Yb, Lu, and an actinoid.

For example, to NCA, a combination of “Zr, Mg, W, Sm”, a combination of “Ti, Mn, Nb, Si, Mo”, or a combination of “Er, Mg” may be added.

For example, to NCM, Ti may be added. For example, to NCM, a combination of “Zr, W”, a combination of “Si, W”, or a combination of “Zr, W, Al, Ti, Co” may be added.

### 2-4-4-9. Surface Covering

Positive electrode 10 may include a composite particle. The composite particle includes a core particle and a covering layer. The core particle includes a positive electrode active material. The covering layer covers at least part of the surface of the core particle. The covering layer may have a thickness from 1 to 3000 nm, or from 5 to 2000 nm, or from 10 to 1000 nm, or from 10 to 100 nm, or from 10 to 50 nm, for example. The thickness of the covering layer may be measured in an SEM (Scanning Electron Microscope) image of a cross section of the particle, and/or the like, for example. More specifically, the composite particle is embedded in a resin material to prepare a sample. With the use of an ion milling apparatus, a cross section of the sample is exposed. For example, an ion milling apparatus with the trade name “ArBlade (registered trademark) 5000” manufactured by Hitachi High-Technologies (or a similar product) may be used. The cross section of the sample is examined by an SEM. For example, an SEM apparatus with the trade name “SU8030” manufactured by Hitachi High-Technologies (or a similar product) may be used. For each of ten composite particles, the thickness of the covering layer is measured in twenty fields of view. The arithmetic mean of a total of 200 thickness measurements is used.

The ratio of the part of the surface of the core particle covered by the covering layer is also called “a covering rate”. The covering rate may be 1% or more, or 10% or more, or 30% or more, or 50% or more, or 70% or more, for example. The covering rate may be 100% or less, or 90% or less, or 80% or less, for example.

For example, the covering rate may be measured by XPS (X-ray Photoelectron Spectroscopy). For example, an XPS apparatus with the trade name “PHI X-tool” manufactured by ULVAC-PHI (or a similar product) may be used. A sample powder consisting of the composite particle is loaded in the XPS apparatus. Narrow scan analysis is carried out. The measurement data is processed with an analysis software. For example, an analysis software with the trade name “MulTiPak” manufactured by ULVAC-PHI (or a similar product) may be used. The measurement data is analyzed to detect a plurality of types of elements. From the area of each peak, the ratio of the detected element is determined. By the following equation (F-3), the covering rate is determined.

θ={I₁/(I₀+I₁)}×100 (F-3)
θ: Covering rate [%]
I₀: Ratio of element attributable to core particle
I₁: Ratio of element attributable to covering layer

For example, when the core particle includes NCM, I₀ represents the total ratio of the elements “Ni, Co, Mn”. For example, when the core particle includes NCA, I₀ represents the total ratio of the elements “Ni, Co, Al”. For example, when the covering layer includes P and B, I₁ represents the total ratio of the elements “P, B”.

The covering layer may include any component. The covering layer may include an elementary substance, organic matter, an inorganic acid salt, an organic acid salt, a hydroxide, an oxide, a carbide, a nitride, a sulfide, a halide, and/or the like, for example. The covering layer may include, for example, at least one selected from the group consisting of B, Al, W, Zr, Ti, Co, F, lithium compound (such as Li₂CO₃, LiHCO₃, LiOH, Li₂O, for example), tungsten oxide (such as WO₃, for example), titanium oxide (such as TiO₂, for example), zirconium oxide (such as ZrO₂, for example), boron oxide, boron phosphate (such as BPO₄, for example), aluminum oxide (such as Al₂O₃, for example), boehmite, aluminum hydroxide, phosphoric acid salt [such as Li₃PO₄, (NH₄)₃PO₄, AlPO₄, for example], boric acid salt (such as Li₂B₄O₇, LiBO₃, for example), polyacrylic acid salt (such as Li salt, Na salt, NH₄ salt), acetic acid salt (such as Li salt, for example), CMC (such as Na salt, Li salt, NH₄ salt), LiNbO₃, Li₂TiO₃, and Li-containing halide (such as LiAlCl₄, LiTiAlF₆, LiYBr₆, LiYCl₆, for example).

### 2-4-4-10. Hollow Particles, Solid Particles

“Hollow particle” refers to a secondary particle in which, in a cross-sectional image thereof, the proportion of the area occupied by its central cavity relative to the entire cross-sectional area of the particle is 30% or more. The proportion of the cavity in the hollow particle may be 40% or more, or 50% or more, or 60% or more, for example. “Solid particle” refers to a secondary particle in which, in a cross-sectional image of the particle, the proportion of the area occupied by its central cavity relative to the entire cross-sectional area of the particle is less than 30%. The proportion of the cavity in the solid particle may be 20% or less, or 10% or less, or 5% or less, for example. The positive electrode active material may be hollow particles, or may be solid particles. A mixture of hollow particles and solid particles may be used. The mixing ratio (mass ratio) between hollow particles and solid particles may be “(hollow particles)/(solid particles)=1/9 to 9/1”, or “(hollow particles)/(solid particles)=2/8 to 8/2”, or “(hollow particles)/(solid particles)=3/7 to 7/3”, or “(hollow particles)/(solid particles)=4/6 to 6/4”, for example.

### 2-4-4-11. Large Particles, Small Particles

“Electrode active material” collectively refers to a positive electrode active material and a negative electrode active material. The electrode active material may have a unimodal particle size distribution (based on the number), for example. The electrode active material may have a multimodal particle size distribution, for example. The electrode active material may have a bimodal particle size distribution, for example. That is, the electrode active material may include large particles and small particles. When the particle size distribution is bimodal, the particle size corresponding to the peak top of the larger particle size is regarded as the particle size of the large particles (d_{L}). The particle size corresponding to the peak top of the smaller particle size is regarded as the particle size of the small particles (d_{S}). The particle size ratio (d_{L}/d_{S}) may be from 2 to 10, or from 2 to 5, or from 2 to 4, for example. d_{L} may be from 8 to 20 μm, or from 8 to 15 μm, for example. d_{S} may be from 1 to 10 μm, or from 1 to 5 μm, for example.

For example, with the use of a waveform analysis software, peak separating processing may be carried out for the particle size distribution. The ratio between the peak area of the large particles (S_{L}) and the peak area of the small particles (S_{S}) may be “S_{L}/S_{S}=1/9 to 9/1”, or “S_{L}/S_{S}=5/5 to 9/1”, or “S_{L}/S_{S}=7/3 to 9/1”, for example.

The number-based particle size distribution is measured by a microscope method. From the electrode active material layer, a plurality of cross-sectional samples are taken. The cross-sectional sample may include a cross section vertical to the surface of the electrode active material layer, for example. By ion milling and/or the like, for example, cleaning is carried out to the side that is to be observed. By SEM, the cross-sectional sample is examined. The magnification for the examination is adjusted in such a way that 10 to 100 particles are contained within the examination field of view. The Feret diameters of all the particles in the image are measured. “Feret diameter” refers to the distance between two points located farthest apart from each other on the outline of the particle. The plurality of the cross-sectional samples are examined to obtain a total of 1000 or more Feret diameters. From the 1000 or more Feret diameters, number-based particle size distribution is created.

The bimodal particle size distribution may be formed by two types of particles mixed together. These two types of particles have different particle size distributions. For example, the two types of particles may have different D50. “D50” refers to a particle size in volume-based particle size distribution at which the cumulative frequency accumulated from the side of small particle sizes reaches 50%. D50 may be measured by laser diffraction. The sample to be measured is powder. For example, the large particles may have a D50 from 8 to 20 μm, or from 8 to 15 μm. For example, the small particles may have a D50 from 1 to 10 μm, or from 1 to 5 μm. The ratio of the D50 of the large particles to the D50 of the small particles may be from 2 to 10, or from 2 to 5, or from 2 to 4, for example. The mixing ratio (mass ratio) between the large particles and the small particles may be “(large particles)/(small particles)=1/9 to 9/1”, or “(large particles)/(small particles)=5/5 to 9/1”, or “(large particles)/(small particles)=7/3 to 9/1”, for example.

The large particles and the small particles may have the same composition, or may have different compositions. For example, the large particles may be NCA and the small particles may be NCM. For example, the large particles may be NCM (0.6≤x) and the small particles may be NCM (x<0.6).

### 2-5. Electrolyte

In the electrolyte, Li ions are dissolved. The electrolyte may be a liquid electrolyte, or may be a gelled electrolyte. The liquid electrolyte may include an electrolyte solution, for example. The electrolyte solution includes a solvent and a solute.

### 2-5-1. Solute

The concentration of the solute may be from 0.5 to 1 mol/L, or from 1 to 1.5 mol/L, or from 1.5 to 2 mol/L, or from 2 to 2.5 mol/L, or from 2.5 to 3 mol/L, for example. The solute includes a supporting salt (a Li salt). The solute may include an inorganic acid salt, an imide salt, an oxalato complex, a halide, and/or the like, for example. The solute may include, for example, at least one selected from the group consisting of LiPF₆, LiBF₄, LiClO₄, LiAsF₆, LiSbF₆, LiN(SO₂F)₂ “LiFSI”, LiN(SO₂CF₃)₂ “LiTFSI”, LiB(C₂O₄)₂ “LiBOB”, LiBF₂(C₂O₄) “LIDFOB”, LiPF₂(C₂O₄)₂ “LiDFOP”, LiPO₂F₂, FSO₃Li, LiI, LiBr, and derivatives of these.

### 2-5-2. Solvent

### 2-5-2-1. Ether-Based Solvent

The electrolyte solution may include an ether-based solvent. The solvent may include HFE and/or the like, for example. HFE may include, for example, at least one selected from the group consisting of a difluoromethyl group, a 2,2-difluoroethyl group, a 2,2,2-trifluoroethyl group, a 1,1,2,2-tetrafluoroethyl group, a 2,2,3,3,3-pentafluoropropyl group, a 2,2,3,3-tetrafluoropropyl group, a 1,1,1,3,3,3-hexafluoroisopropyl group, a 1,1,2,3,3,3-hexafluoropropyl group, a 2,2,3,3,4,4,4-heptafluorobutyl group, a 2,2,3,3,4,4-hexafluorobutyl group, and a 2,2,3,3,4,4,5,5-octafluoropentyl group.

HFE may include, for example, at least one selected from the group consisting of 1,1,2,2-tetrafluoroethyl 2,2,3,3-tetrafluoropropyl ether (TTE), 2,2,2-trifluoroethyl ether, difluoromethyl 2,2,3,3-tetrafluoropropyl ether, 2,2,3,3-tetrafluoropropyl 1,1,2,3,3,3-hexafluoropropyl ether, 2,2,3,3,4,4,5,5-octafluoropentyl 1,1,2,2-tetrafluoroethyl ether, and derivatives of these.

The solvent may also include an ether other than HFE (hereinafter also called “a second ether”). The second ether may include, for example, at least one selected from the group consisting of tetrahydrofuran (THF), 1,4-dioxane (DOX), 1,3-dioxolane (DOL), 1,2-dimethoxyethane (DME), 1,2-diethoxyethane (DEE), ethylglyme, triglyme, tetraglyme, and derivatives of these. For example, the solvent may include the second ether (such as DME) in an amount from 1 to 50% in terms of volume fraction, with the remainder being made up of HFE. For example, the solvent may include the second ether in an amount of 10 to 40% in terms of volume fraction, with the remainder being made up of HFE.

### 2-5-2-2. Carbonate-Based Solvent

The electrolyte solution may include a carbonate-based solvent (a carbonate-ester-based solvent), for example. The solvent may include a cyclic carbonate, a chain carbonate, a fluorinated carbonate, and/or the like, for example. The solvent may include, for example, at least one selected from the group consisting of ethylene carbonate (EC), propylene carbonate (PC), butylene carbonate (BC), dimethyl carbonate (DMC), diethyl carbonate (DEC), ethyl methyl carbonate (EMC), monofluoroethylene carbonate (FEC), difluoroethylene carbonate, 4,4-difluoroethylene carbonate, trifluoroethylene carbonate, perfluoroethylene carbonate, fluoropropylene carbonate, difluoropropylene carbonate, and derivatives of these.

The solvent may include a cyclic carbonate (such as EC, PC, FEC) and a chain carbonate (such as EMC, DMC, DEC). The mixing ratio between the cyclic carbonate and the chain carbonate (volume ratio) may be “(cyclic carbonate)/(chain carbonate)=1/9 to 4/6”, or “(cyclic carbonate)/(chain carbonate)=2/8 to 3/7”, or “(cyclic carbonate)/(chain carbonate)=3/7 to 4/6”, for example.

The solvent may include a cyclic carbonate (such as EC, PC) and a fluorinated cyclic carbonate (such as FEC). The mixing ratio between the cyclic carbonate and the fluorinated cyclic carbonate (volume ratio) may be “(cyclic carbonate)/(fluorinated cyclic carbonate)=99/1 to 90/10”, or “(cyclic carbonate)/(fluorinated cyclic carbonate)=9/1 to 1/9”, or “(cyclic carbonate)/(fluorinated cyclic carbonate)=9/1 to 7/3”, or “(cyclic carbonate)/(fluorinated cyclic carbonate)=3/7 to 1/9”, for example.

The solvent may include EC, FEC, EMC, DMC, and DEC, for example. The volume ratio of these components may satisfy the relationship represented by the following equation (E-1), for example.

V_{EC}+V_{FEC}+V_{EMC}+V_{DMC}+V_{DEC}=10 (E-1)

In the above formula, each of V_{EC}, V_{FEC}, V_{EMC}, V_{DMC}, and V_{DEC} represents the volume ratio of EC, FEC, EMC, DMC, and DEC, respectively.

The following relationships are satisfied: 1≤V_{EC}≤4, 0≤V_{FEC}≤3, V_{EC}+V_{FEC}≤4, 0≤V_{EMC}≤9, 0≤V_{DMC}≤9, 0≤V_{DEC}≤9, 6≤V_{EMC}+V_{DMC}+V_{DEC}≤9.

In the above equation (E-1),
the relationship of 1≤V_{EC}≤2 or 2≤V_{EC}≤3 may be satisfied, for example;
the relationship of 1≤V_{FEC}≤2 or 2≤V_{FEC}≤4 may be satisfied, for example;
the relationship of 3≤V_{EMC}≤4 or 6≤V_{EMC}≤8 may be satisfied, for example;
the relationship of 3≤V_{DMC}≤4 or 6≤V_{DMC}≤8 may be satisfied, for example; and
the relationship of 3≤V_{DEC}≤4 or 6≤V_{DEC}≤8 may be satisfied, for example.

The solvent may have a composition of “EC/EMC-3/7”, “EC/DMC=3/7”, “EC/FEC/DEC=1/2/7”, “EC/DMC/EMC-3/4/3”, “EC/DMC/EMC=3/3/4”, “EC/FEC/DMC/EMC=2/1/4/3”, “EC/FEC/DMC/EMC=1/2/4/3”, “EC/FEC/DMC/EMC=2/1/3/4”, “EC/FEC/DMC/EMC=1/2/3/4” (volume ratio), and/or the like, for example.

### 2-5-3. Additive

The electrolyte solution may include any additive. The amount to be added (the mass fraction to the total amount of the electrolyte solution) may be from 0.01 to 5%, or from 0.05 to 3%, or from 0.1 to 1%, for example. The additive may include an SEI (Solid Electrolyte Interphase) formation promoter, an SEI formation inhibitor, a gas generation agent, an overcharging inhibitor, a flame retardant, an antioxidant, an electrode-protecting agent, a surfactant, and/or the like, for example.

The additive may include, for example, at least one selected from the group consisting of vinylene carbonate (VC), vinylethylene carbonate (VEC), 1,3-propane sultone (PS), tert-amylbenzene, 1,4-di-tert-butylbenzene, biphenyl (BP), cyclohexylbenzene (CHB), ethylene sulfite (ES), propane sultone (PS), ethylene sulfate (DTD), y-butyrolactone, phosphazene compound, carboxylate ester [such as methyl formate (MF), methyl acetate (MA), methyl propionate (MP), diethyl malonate (DEM), for example], fluorobenzene (such as monofluorobenzene (FB), 1,2-difluorobenzene, 1,3-difluorobenzene, 1,4-difluorobenzene, 1,2,3-trifluorobenzene, 1,2,4-trifluorobenzene, 1,3,5-trifluorobenzene, 1,2,3,4-tetrafluorobenzene, 1,2,3,5-tetrafluorobenzene, 1,2,4,5-tetrafluorobenzene, pentafluorobenzene, hexafluorobenzene, for example), fluorotoluene (such as 2-fluorotoluene, 3-fluorotoluene, 4-fluorotoluene, 2,3-difluorotoluene, 2,4-difluorotoluene, 2,5-difluorotoluene, 2,6-difluorotoluene, 3,4-difluorotoluene, octafluorotoluene, for example), benzotrifluoride (such as benzotrifluoride, 2-fluorobenzotrifluoride, 3-fluorobenzotrifluoride, 4-fluorobenzotrifluoride, 2-methylbenzotrifluoride, 3-methylbenzotrifluoride, 4-methylbenzotrifluoride, for example), fluoroxylene (such as 3-fluoro-o-xylene, 4-fluoro-o-xylene, 2-fluoro-m-xylene, 5-fluoro-m-xylene, for example), sulfur-containing heterocyclic compound (such as benzothiazole, 2-methylbenzothiazole, tetrathiafulvalene, for example), nitrile compound (such as adiponitrile, succinonitrile, for example), phosphate (such as trimethyl phosphate, triethyl phosphate, for example), carboxylic anhydride (such as acetic anhydride, propionic anhydride, oxalic anhydride, succinic anhydride, maleic anhydride, phthalic anhydride, benzoic anhydride, for example), alcohol (such as methanol, ethanol, n-propyl alcohol, ethylene glycol, diethylene glycol monomethyl ether, for example), and derivatives of these.

The components described above as the solute and the solvent may be used as a trace component (an additive). The additive may include, for example, at least one selected from the group consisting of LiBF₄, LiFSI, LiTFSI, LiBOB, LIDFOB, LiDFOP, LiPO₂F₂, FSO₃Li, LiI, LiBr, HFE, DOX, PC, FEC, and derivatives of these.

### 2-5-4. Ionic Liquid

The liquid electrolyte may include an ionic liquid. The liquid electrolyte may include, for example, at least one selected from the group consisting of a sulfonium salt, an ammonium salt, a pyridinium salt, a piperidinium salt, a pyrrolidinium salt, a morpholinium salt, a phosphonium salt, an imidazolium salt, and derivatives of these.

### 2-5-5. Gelled Electrolyte

The gelled electrolyte may include a liquid electrolyte and a polymer material. The polymer material may form a polymer matrix. The polymer material may include, for example, at least one selected from the group consisting of PVdF, PVdF-HFP, PAN, PVdF-PAN, polyethylene oxide (PEO), polyethylene glycol (PEG), and derivatives of these.

### 2-6. Separator

Separator 30 is capable of separating positive electrode 10 from negative electrode 20. Separator 30 is electrically insulating. Separator 30 may include, for example, at least one selected from the group consisting of a resin film, an inorganic particle layer, and an organic particle layer. Separator 30 may include a resin film and an inorganic particle layer, for example.

### 2-6-1. Resin Film

The resin film is porous. The resin film may include a microporous film, a nonwoven fabric, and/or the like, for example. The resin film includes a resin skeleton. The resin skeleton may be contiguous in mesh form, for example. Gaps in the resin skeleton form pores. The resin film allows the electrolyte to permeate therethrough. The resin film may have an average pore size of 1 μm or less, for example. The resin film may have an average pore size from 0.01 to 1 μm, or from 0.1 to 0.5 μm, for example. “Average pore size” may be measured by mercury porosimetry. The resin film may have a Gurley value from 50 to 250 s/100 cm³, for example. “Gurley value” may be measured by a Gurley test method.

The resin film may include, for example, at least one selected from the group consisting of an olefin-based resin, a polyurethane-based resin, a polyamide-based resin, a cellulose-based resin, a polyether-based resin, an acrylic-based resin, a polyester-based resin, and the like. The resin film may include, for example, at least one selected from the group consisting of polyethylene (PE), polypropylene (PP), polyamide (PA), polyamide-imide (PAI), polyimide (PI), aromatic polyamide (aramid), and polyphenylene ether (PPE), and derivatives of these. The resin film may be formed by stretching, phase separation, and/or the like, for example. The resin film may have a thickness from 5 to 50 μm, or from 10 to 25 μm, for example.

The resin film may have a monolayer structure. The resin film may consist of a PE layer, for example. A skeleton of a PE layer is formed of PE. The PE layer may have shut-down function. The resin film may have a multilayer structure, for example. The resin film may include a PP layer and a PE layer, for example. A skeleton of a PP layer is formed of PP. The resin film may have a three-layer structure, for example. The resin film may be formed by stacking a PP layer, a PE layer, and a PP layer in this order, for example. The thickness of the PE layer may be from 5 to 20 μm, for example. The thickness of the PP layer may be from 3 to 10 μm, for example.

### 2-6-2. Inorganic Particle Layer

The inorganic particle layer may be formed on the surface of the resin film. The inorganic particle layer may be formed on only one side of the resin film, or may be formed on both sides of the resin film. The inorganic particle layer may be formed on the side facing positive electrode 10, or may be formed on the side facing negative electrode 20. The inorganic particle layer may be formed on the surface of positive electrode 10, or may be formed on the surface of negative electrode 20.

The inorganic particle layer is porous. The inorganic particle layer includes inorganic particles. The inorganic particles may also be called “an inorganic filler”. Gaps between the inorganic particles form pores. The inorganic particle layer may have a thickness from 0.5 to 10 μm, or from 1 to 5 μm, for example. The inorganic particles may include a heat-resistant material, for example. The inorganic particle layer that includes a heat-resistant material is also called “HRL (Heat Resistance Layer)”. The inorganic particles may include at least one selected from the group consisting of boehmite, alumina, zirconia, titania, magnesia, silica, and the like. The inorganic particles may have any shape. The inorganic particles may be spherical, rod-like, plate-like, fibrous, and/or the like, for example. The inorganic particles may have a D50 from 0.1 to 10 μm, or from 0.5 to 3 μm, for example. The inorganic particle layer may further include a binder. The binder may include, for example, at least one selected from the group consisting of an acrylic-based resin, a polyamide-based resin, a fluorine-based resin, an aromatic-polyether-based resin, and a liquid-crystal-polyester-based resin, and the like.

### 2-6-3. Organic Particle Layer

Separator 30 may include an organic particle layer, for example. Separator 30 may include an organic particle layer instead of the resin film, for example. Separator 30 may include an organic particle layer instead of the inorganic particle layer, for example. Separator 30 may include both the resin film and an organic particle layer. Separator 30 may include both the inorganic particle layer and an organic particle layer. Separator 30 may include the resin film, the inorganic particle layer, and an organic particle layer.

The organic particle layer may have a thickness from 0.1 to 50 μm, or from 0.5 to 20 μm, or from 0.5 to 10 μm, or from 1 to 5 μm, for example. The organic particle layer includes organic particles. The organic particles may also be called “an organic filler”. The organic particles may include a heat-resistant material. The organic particles may include, for example, at least one selected from the group consisting of PE, PP, PTFE, PI, PAI, PA, aramid, and the like. The organic particles may be spherical, rod-like, plate-like, fibrous, and/or the like, for example. The organic particles may have a D50 from 0.1 to 10 μm, or from 0.5 to 3 μm, for example. Separator 30 may include a mixed layer, for example. The mixed layer includes both inorganic particles and organic particles.

### 2-7. Cell Configuration

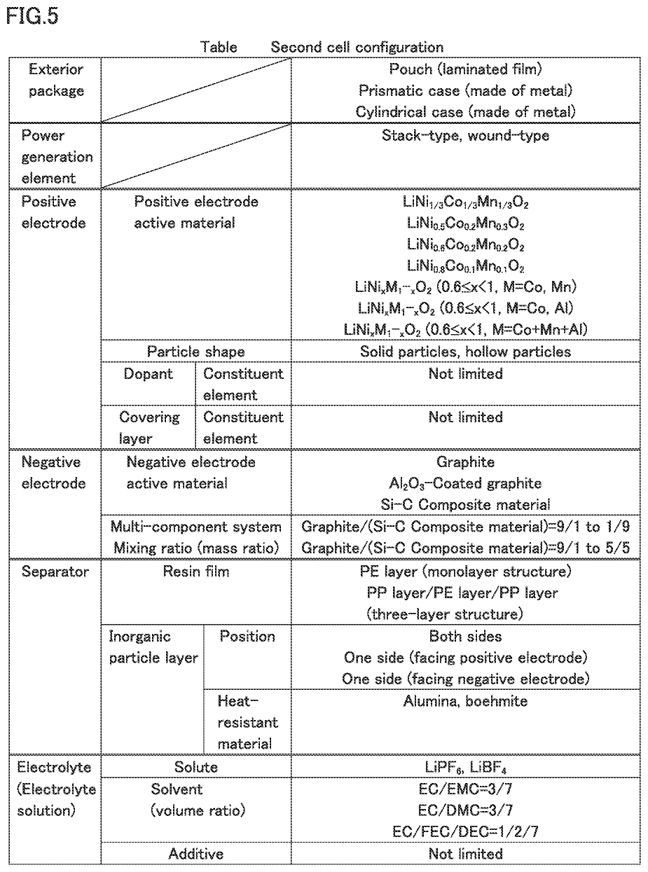

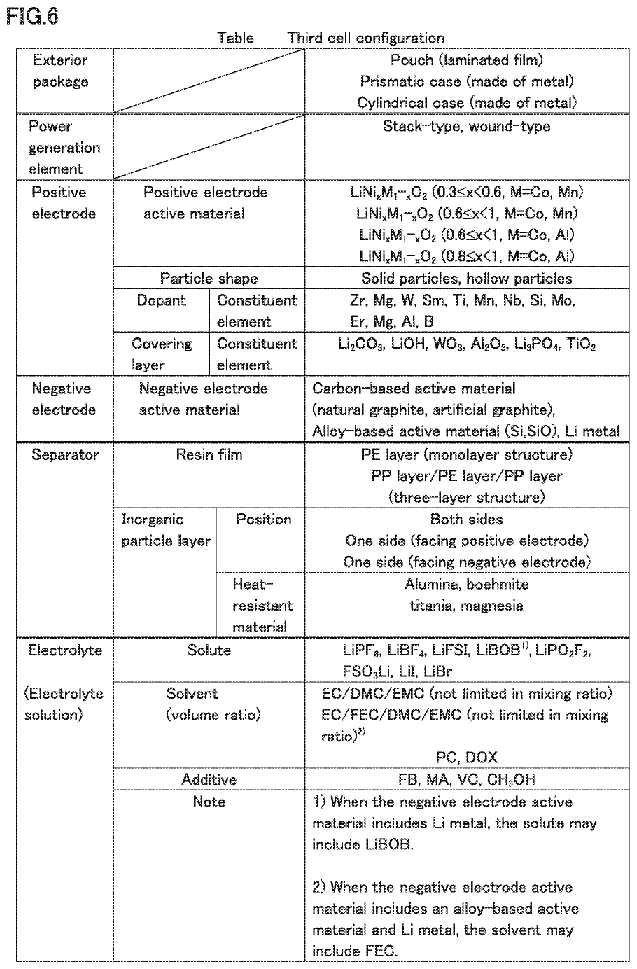

FIG. 4 is a table showing a first cell configuration. FIG. 5 is a table showing a second cell configuration. FIG. 6 is a table showing a third cell configuration. In each table, when a plurality of materials are described in a single cell, this description is intended to mean one of them as well as a combination of them. For example, when materials “α, β, γ” are described in a single cell, this description is intended to mean “at least one selected from the group consisting of α, β, and γ”. Certain elements may be extracted from the first to third cell configurations and optionally combined together.

For example, the present embodiment may be incorporated into the first to third cell configurations. For example, the present embodiment may be combined with the first to third cell configurations. For example, the present embodiment may replace part of the first to third cell configurations. For example, the negative electrode in the first cell configuration may be replaced by the negative electrode according to the present embodiment (negative electrode current collector 21, pillar layer 22). For example, the negative electrode in the first cell configuration may be used in combination with the negative electrode according to the present embodiment. Combining the first to third cell configurations with the present embodiment, for example, may improve cell performance.

### 3. Method of Producing Negative Electrode

Negative electrode 20 may be produced by any method. For example, electrically-insulating pillars 1 may be formed by CVD (Chemical Vapor Deposition), ALD (Atomic Layer Deposition), PVD (Physical Vapor Deposition), EPD (Electrophoretic Deposition), selective dry etching, laser processing, additive manufacturing, and/or the like. For example, electrically-insulating pillars 1 may be formed by photolithography. In the following, a method for producing negative electrode 20 by photolithography is described as an example.

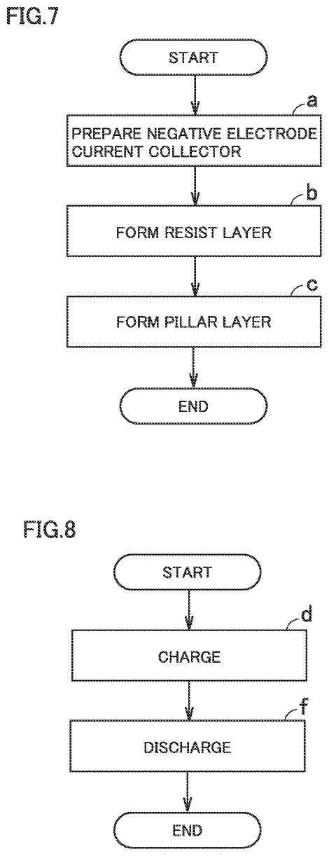

FIG. 7 is a schematic flowchart illustrating a method of producing a negative electrode according to the present embodiment. Hereinafter, “the method of producing a negative electrode according to the present embodiment” may also be simply called “the present production method”. The present production method includes “(a) preparing a negative electrode current collector”, “(b) forming a resist layer”, and “(c) forming a pillar layer”.

### 3-1. (a) Preparing Negative Electrode Current Collector

The present production method includes preparing negative electrode current collector 21. The details of negative electrode current collector 21 are as described above. Negative electrode current collector 21 may be produced, or may be obtained from the market. For example, electrodeposited copper foil, rolled copper foil, and/or the like may be prepared as negative electrode current collector 21.

### 3-2. (b) Forming Resist Layer

The present production method includes forming a resist layer (not illustrated) by placing a resist material on the surface of negative electrode current collector 21. The resist material may be liquid-type or may be dry-film-type, for example. When the resist material is liquid-type, for example, the resist material may be applied to the surface of negative electrode current collector 21 to form the resist layer. For example, application of the resist material may be carried out with a spin coater and/or the like. When the resist material is dry-film-type, the dry film may be placed on the surface of negative electrode current collector 21 to form the resist layer. The thickness of the resist layer may correspond to the height of electrically-insulating pillar 1. The thickness of the resist layer may be adjusted depending on the desired height of electrically-insulating pillar 1.

### 3-3. (c) Forming Pillar Layer

The present production method includes forming pillar layer 22 by selectively removing a part of the resist layer. An example case where the resist material is negative-type is described. The resist layer is covered with a photomask. The pattern on the photomask may be changed to adjust the bottom face shapes and positions of electrically-insulating pillars 1. Through the photomask, light is applied to the resist layer, for example. The wavelength of the light is selected so as to suit the resist material. For example, ultraviolet (UV) rays may be applied. By the light application (exposure to light), a photosensitized portion and a non-photosensitized portion are formed. The photosensitized portion is a portion irradiated with the light. The photosensitized portion may be hardened. The non-photosensitized portion is a portion not irradiated with the light. With the use of a developer solution, the non-photosensitized portion may be dissolved. The developer solution is selected so as to suit the resist material. The developer solution may include caustic soda and/or the like, for example. The non-photosensitized portion may be removed to form electrically-insulating pillars 1 (the photosensitized portion). More specifically, a part of the resist layer may be selectively removed to form pillar layer 22.

### 4. Method of Charging and Discharging

FIG. 8 is a schematic flowchart illustrating a method of charging and discharging according to the present embodiment. Hereinafter, “the method of charging and discharging according to the present embodiment” may also be simply called “the present charging/discharging method”. The present charging/discharging method includes “(d) charging” and “(f) discharging”. The order illustrated in FIG. 8 is merely an example. The present charging/discharging method includes “(d) charging” and “(f) discharging” in any order as long as it includes at least one “(d) charging” and at least one “(f) discharging”. For example, charging may be successively carried out twice, followed by discharging. For example, “(d) charging” and “(f) discharging” may be carried out with a pause between them.

### 4-1. (d) Charging

The present charging/discharging method includes charging cell 100. Charging includes deposition of Li metal 2a in gap 2. During charging, Li metal 2a may start to be deposited at the surface of negative electrode current collector 21 (see FIG. 1). Deposition of Li metal 2a may proceed in the thickness direction of pillar layer 22 (the Z-axis direction). Before Li metal 2a is exposed from pillar layer 22, charging completes. Charging is carried out in such a manner that Li metal 2a is present only inside the pillar layer 22, and thereby expansion of cell 100 may be reduced.

In a plan view (in the XY plane), Li metal 2a may become deposited so as to extend in mesh form (see FIG. 3). This is because a dispersed phase is formed by electrically-insulating pillars 1. When Li metal 2a forms a contiguous phase within pillar layer 22, the amount of Li metal 2a deposition in the in-plane direction is expected to be uniform. The in-plane direction refers to any direction that is orthogonal to the thickness direction (namely, to the Z-axis direction). When the amount of Li metal 2a deposition in the in-plane direction is uniform, expansion of cell 100 is expected to be further reduced.

### 4-2. (f) Discharging

The present charging/discharging method includes discharging cell 100. Discharging includes dissolution of Li metal 2a present in gap 2 into the electrolyte. During discharging, Li metal 2a may start to be dissolved at a side close to positive electrode 10. Dissolution of Li metal 2a may proceed in the thickness direction of pillar layer 22. The entire amount of Li metal 2a may be dissolved, or part of Li metal 2a may be dissolved. It is conceivable that dissolution of Li metal 2a is less likely to cause a change in the contour dimensions of pillar layer 22 (framework). As a result of dissolution of Li metal 2a occurring only inside the pillar layer 22, a volume change (shrinkage) of cell 100 may be reduced.

### 5. Battery System

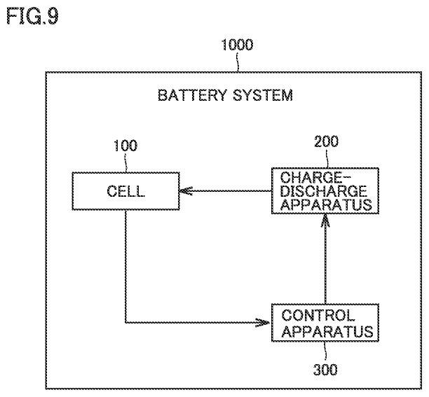

FIG. 9 is a conceptual view illustrating a battery system according to the present embodiment. A battery system 1000 may be mounted on an electric vehicle and/or the like, for example. Battery system 1000 may include cell 100, a charge-discharge apparatus 200, and a control apparatus 300, for example.

Battery system 1000 may include a single cell 100, or may include a plurality of cells 100. The plurality of cells 100 may form a module or a battery pack. Charge-discharge apparatus 200 and control apparatus 300 are capable of implementing the present charging/discharging method (FIG. 8). Charge-discharge apparatus 200 either charges or discharges cell 100. Control apparatus 300 may include various sensors (such as a current sensor, a voltage sensor, a temperature sensor). Based on various types of information acquired by the sensor, control apparatus 300 may control the amount of current and/or the like, for example. For example, charge-discharge apparatus 200 may be integrally formed with control apparatus 300. For example, control apparatus 300 may include charge-discharge apparatus 200.

### EXAMPLES

### 6. Experiments

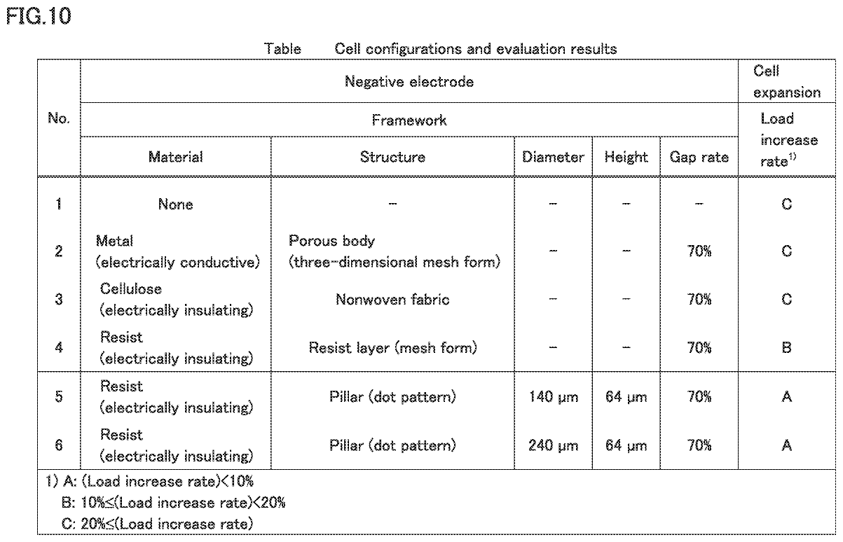

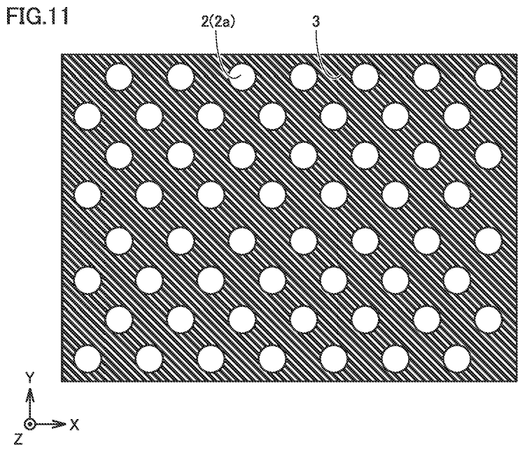

FIG. 10 is a table showing cell configurations and evaluation results. In the manner described below, cells according to Nos. 1 to 6 were produced. Hereinafter, “the cell according to No. 1” may be simply referred to as “No. 1” and/or the like, for example.

### 6-1. Producing Cell

No. 1

A positive electrode active material (LiNi_{0.5}Co_{0.2}Mn_{0.3}O₂), a conductive material (AB), a binder (PVdF), and a dispersion medium (N-methyl-2-pyrrolidone) were mixed together to form a slurry. The mixing ratio was “(positive electrode active material)/(conductive material)/binder=90/5/5 (mass ratio)”. As a positive electrode current collector, an Al foil (thickness, 15 μm) was prepared. The slurry was applied to the surface of the positive electrode current collector to form a coating film. The resulting coating film was dried to form a positive electrode active material layer. The resulting positive electrode active material layer was pressed to produce a positive electrode.

As a negative electrode current collector, a Cu foil (thickness, 10 μm) was prepared. As a separator, a resin film (thickness, 20 μm) was prepared. The resin film had a three-layer structure (PP layer/PE layer/PP layer). The positive electrode, the separator, and the negative electrode current collector were stacked to form a power generation element. As an exterior package, a pouch made of an Al-laminated film was prepared. The power generation element and a liquid electrolyte were sealed into the exterior package to produce a cell.

The liquid electrolyte included the below components.
Solvent: DME/TTE=1/2 (volume ratio)
Solute: LiFSI (1.8 mol/L)

No. 2

As a framework, a metal porous body was prepared. The metal porous body included an electrically-conductive skeleton. The metal porous body was stacked on the negative electrode current collector to produce a negative electrode. The positive electrode, the separator, and the negative electrode were stacked to form a power generation element. Except for these, in the same manner as for No. 1, a cell was produced. The metal porous body had a porosity of 70%. In the table in FIG. 10, for the sake of convenience, the porosity of the metal porous body is given in the “Gap rate” cell.

No. 3

As a framework, a nonwoven fabric was prepared. The nonwoven fabric was formed of cellulose fibers. The cellulose fibers were electrically insulating. The nonwoven fabric was stacked on the negative electrode current collector to produce a negative electrode. Except for this, in the same manner as for No. 2, a cell was produced. The nonwoven fabric had a porosity of 70%. In the table in FIG. 10, for the sake of convenience, the porosity of the nonwoven fabric is given in the “Gap rate” cell.

No. 4

A dry-film resist (hereinafter “a dry film”) was prepared. The dry film was placed on the negative electrode current collector to form a resist layer. The resulting resist layer was covered with a photomask. By photolithography, a part of the resist layer was removed.

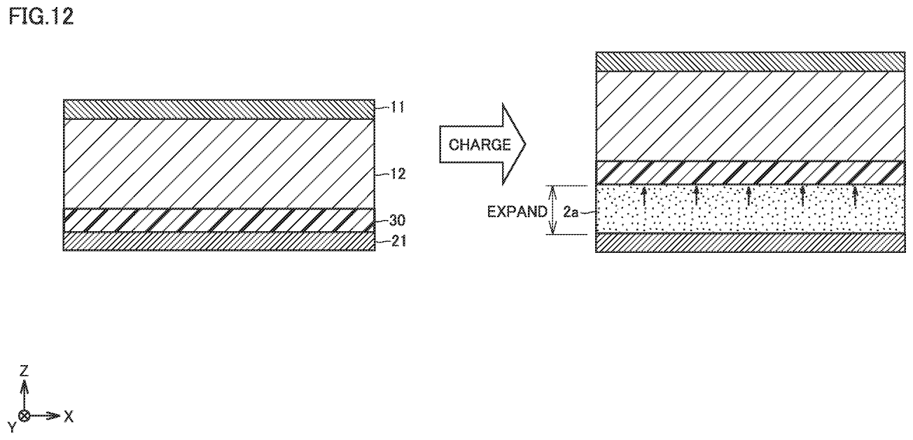

FIG. 11 is a schematic plan view illustrating a framework of No. 4. A resist layer 3 is left in mesh form (in two-dimensional mesh form). Through holes (gaps 2) are formed in dot pattern. Except for this, in the same manner as for No. 2, a cell was produced.

No. 5

The pattern on the photomask was changed so as to leave the resist layer in dot pattern. That is, a plurality of electrically-insulating pillars 1 (pillar layer 22) were formed (see FIG. 3). Except for this, in the same manner as for No. 4, a cell was produced.

No. 6

Except that the diameter of the electrically-insulating pillars was changed, in the same manner as for No. 5, a cell was produced (see FIG. 10).

### 6-2. Evaluation

On the cell, a restraint jig was mounted. The restraint jig restrains the outside of the cell. The dimensions of the restraint jig are fixed. By the restraint jig, expansion of the cell is limited. This restraining method may also be called “fixed-dimension restraining”, “fixed-dimension securing”, and/or the like. The restraint jig is equipped with a load cell. The load cell measures the restraining load. During charging, as the cell expands, force is applied to the restraint jig, and thereby the restraining load increases (the thickness of the cell does not substantially change).

In a charge-discharge apparatus, the cell was set. At a current density of 1 mA/cm², until the voltage of the cell reached 4.2 V, constant-current charging was carried out. By the following equation (F-4), the load increase rate was determined.

ΔL={(L₁−L₀)/L₀}×100 (F-4)
ΔL: Load increase rate [%]
L₁: Restraining load after charging
L₀: Restraining load before charging (which was “L₀=1.3 MPa” in the present evaluation)

In the column “Load increase rate” in the table in FIG. 10, “A” indicates a load increase rate of less than 10%. “B” indicates a load increase rate not less than 10% and less than 20%. “C” indicates a load increase rate of 20% or more. It is conceivable that the lower the load increase rate, the more reduced the expansion of the cell taking place concomitantly with Li metal deposition.

### 6-3. Results

No. 1 has a high load increase rate. FIG. 12 is a conceptual view illustrating the deposition behavior of No. 1. No. 1 does not include a framework. As a result of charging, Li metal 2a becomes deposited on the surface of negative electrode current collector 21. It is conceivable that Li metal 2a thus deposited pushes aside the surrounding members to cause expansion of the cell.

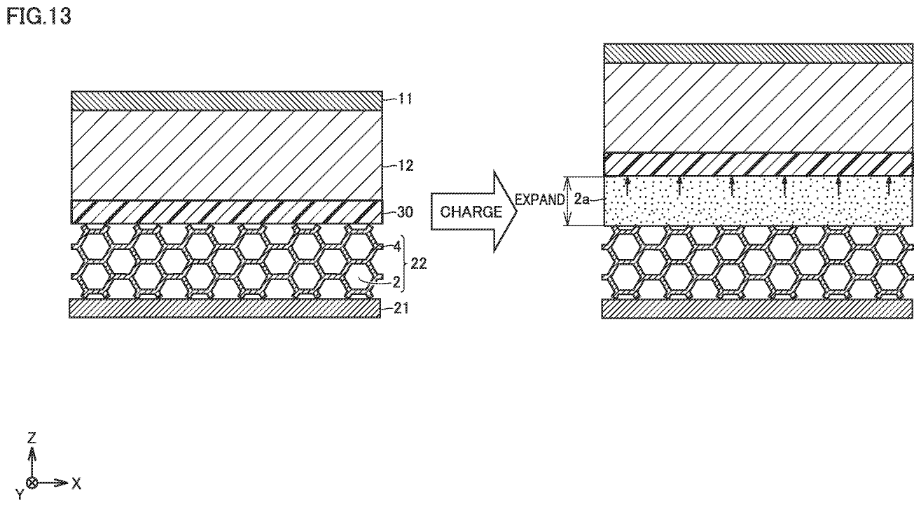

No. 2 has a high load increase rate. FIG. 13 is a conceptual view illustrating the deposition behavior of No. 2. In No. 2, the framework includes an electrically-conductive skeleton 4. Deposition of Li metal 2a starts at the edge of the framework. Li metal 2a grows in a direction toward positive electrode 10. It is conceivable that Li metal 2a thus deposited pushes aside the surrounding members to cause expansion of the cell.

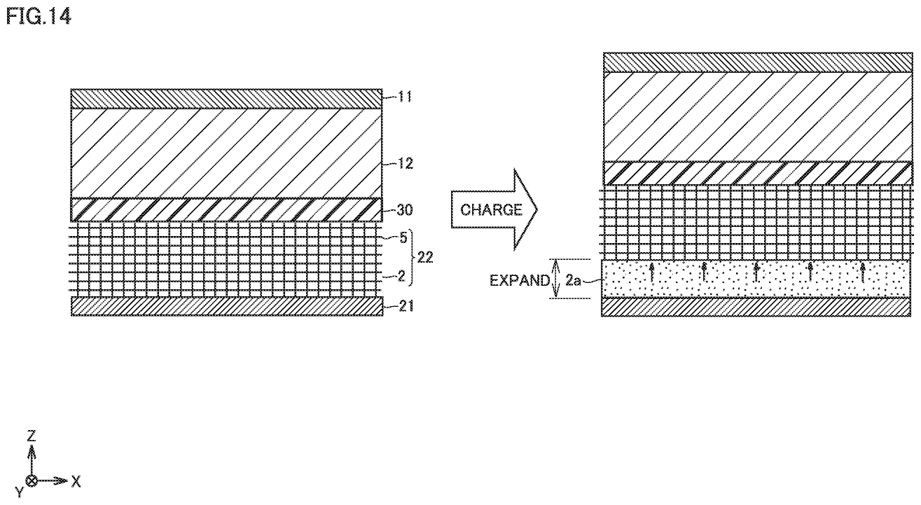

No. 3 has a high load increase rate. FIG. 14 is a conceptual view illustrating the deposition behavior of No. 3. The framework in No. 3 is a nonwoven fabric 5. As a result of charging, Li metal 2a becomes deposited on the surface of negative electrode current collector 21. Li metal 2a thus deposited cannot enter into nonwoven fabric 5 and, thereby, becomes deposited in a manner that it pushes aside the nonwoven fabric 5. It may be because Li metal 2a tends not to enter into gaps between fibers that are entangled to each other in a complex fashion.

Each of Nos. 5 and 6 has a low load increase rate. The framework in Nos. 5 and 6 is pillar layer 22 (a plurality of electrically-insulating pillars 1). As a result of charging, Li metal 2a becomes deposited on the surface of negative electrode current collector 21 (see FIG. 1). Li metal 2a becomes deposited in gap 2 between electrically-insulating pillars 1. Li metal 2a grows inside the gap 2. It is conceivable that even when the amount of deposited Li metal 2a increases, the contour dimensions of pillar layer 22 tend not to change. This may reduce the expansion of the cell.

No. 4 has a high load increase rate as compared to Nos. 5 and 6. In No. 4, the resist forms a contiguous phase and Li metal forms a dispersed phase. It is conceivable that due to the presence of isolated Li metal, the amount of Li metal deposition in the in-plane direction tends to become nonuniform. On the other hand, in Nos. 5 and 6, the resist (electrically-insulating pillars) forms a dispersed phase and Li metal forms a contiguous phase. It is conceivable that due to Li metal forming a contiguous phase, the amount of Li metal deposition in the in-plane direction tends to become uniform. It is conceivable that due to the amount of Li metal deposition in the in-plane direction being uniform, expansion of the cell is reduced.

What is claimed is:

1. A lithium metal secondary battery comprising:
a positive electrode;
a negative electrode; and
an electrolyte, wherein
the negative electrode includes a negative electrode current collector and a pillar layer,
the pillar layer is placed on a surface of the negative electrode current collector,
the pillar layer includes a plurality of electrically-insulating pillars,
each of the plurality of electrically-insulating pillars extends in a direction heading from the surface of the negative electrode current collector toward the positive electrode,
lithium ions are dissolved in the electrolyte,
a charging reaction of the negative electrode is a deposition reaction of a lithium metal occurring in a gap between the electrically-insulating pillars, and
a discharging reaction of the negative electrode is a dissolution reaction of the lithium metal occurring in the gap.

2. The lithium metal secondary battery according to claim 1, wherein each of the plurality of electrically-insulating pillars includes a resist material.

3. The lithium metal secondary battery according to claim 1, wherein
each of the plurality of electrically-insulating pillars has an aspect ratio of 1 or less, and the aspect ratio is determined by the following equation (F-1):
A_{R}=H/D (F-1)
where A_{R} represents the aspect ratio, H represents a height of the electrically-insulating pillar, and D represents a diameter of the electrically-insulating pillar.

4. The lithium metal secondary battery according to claim 1, wherein each of the plurality of electrically-insulating pillars has a diameter from 100 to 300 μm and a height from 1 to 100 μm.

5. The lithium metal secondary battery according to claim 1, wherein
the electrolyte includes a solvent and a solute,
the solvent includes a hydrofluoroether, and
the solute includes an imide salt.

6. The lithium metal secondary battery according to claim 1, wherein
the pillar layer has a gap rate from 50 to 95%, and
the gap rate is determined by the following equation (F-2):
P₀={(S₀−S₁)/S₀}×100 (F-2)
where P₀ represents the gap rate, S₀ represents an area of a region on which the pillar layer is placed, within an area of the negative electrode current collector, and S₁ represents a total area to which the plurality of electrically-insulating pillars are adhered.

7. A method of producing a negative electrode for the lithium metal secondary battery according to claim 1, the method comprising:
(a) preparing the negative electrode current collector;
(b) forming a resist layer by placing a resist material on the surface of the negative electrode current collector; and
(c) forming the pillar layer by selectively removing a part of the resist layer.

8. A method of charging and discharging a lithium metal secondary battery, the method comprising:
(d) charging a lithium metal secondary battery; and
(f) discharging the lithium metal secondary battery, wherein
the lithium metal secondary battery comprises a positive electrode, a negative electrode, and an electrolyte,
the negative electrode includes a negative electrode current collector and a pillar layer,
the pillar layer is placed on a surface of the negative electrode current collector,
the pillar layer includes a plurality of electrically-insulating pillars,
each of the plurality of electrically-insulating pillars extends in a direction heading from the surface of the negative electrode current collector toward the positive electrode,
lithium ions are dissolved in the electrolyte,
the above (d) includes deposition of a lithium metal in a gap between the electrically-insulating pillars, and
the above (f) includes dissolution of the lithium metal in the gap.

9. The method of charging and discharging a lithium metal secondary battery according to claim 8, wherein the lithium metal becomes deposited so as to extend in mesh form in a plan view.
